(19) United States
(12) Patent Application Publication
(10) Pub. No.: US 2015/0144200 A1
(43) Pub. Date: May 28, 2015

(54) COMPOSITION AND ELECTRONIC DEVICE USING THE SAME

(71) Applicant: Sumitomo Chemical Company, Limited, Tokyo (JP)

(72) Inventors: Kai Iketaki, Tsukuba-shi (JP); Ken Yoshimura, Tsukuba-shi (JP)

(73) Assignee: SUMITOMO CHEMICAL COMPANY, LIMITED, Tokyo (JP)

(21) Appl. No.: 14/405,099

(22) PCT Filed: May 24, 2013
(86) PCT No.: PCT/JP2013/065124

§ 371 Date: Dec. 2, 2014

(30) Foreign Application Priority Data
Jun. 4, 2012 (JP) 2012-126748

(51) Int. Cl. H01L 51/00; H01L 51/44

(52) U.S. Cl. CPC H01L 51/0036; H01L 51/441; H01L 51/4253
USPC 136/263; 252/500; 257/40

(57) ABSTRACT

A composition comprising a first compound, a second compound and a third compound, wherein the first compound is a polymer compound having a constitutional unit represented by the formula (1), the second compound is a polymer compound having a constitutional unit represented by the formula (2) and the third compound is a compound different from the first compound and the second compound:

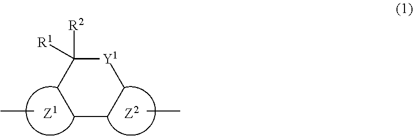

wherein R¹, R², Y¹, Z¹ and ring Z² are as defined herein,

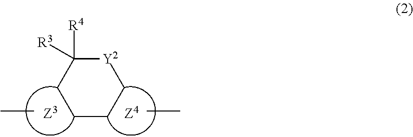

wherein R³, R⁴, Y², Z³ and Z⁴ are as defined herein. An organic photoelectric conversion device having a first electrode and a second electrode, having an active layer between the first electrode and the second electrode, and comprising the above-described composition in the active layer.

### TECHNICAL FIELD

The present invention relates to a composition and an electronic device using the same.

### BACKGROUND ART

Recently, energy generated by using a solar cell is expected as new energy. As the solar cell, a crystalline silicon solar cell is produced on a large scale. The crystalline silicon solar cell, however, has a problem of high production cost since its production process includes a step of melting silicon under high temperature condition.

In contrast, an organic film solar cell does not need the high temperature process used in the production process of a silicon solar cell and can possibly be produced only by a coating process, thus, is expected as a low cost solar cell. There is a suggestion on a composition composed of a phenyl-C61-butyric acid methyl ester and a polymer compound consisting of a repeating unit (A) and a repeating unit (B), as a composition used in an organic film solar cell which is one embodiment of organic photoelectric conversion devices (Patent document 1).

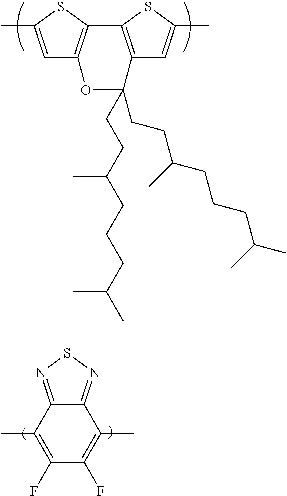

repeating unit (A) repeating unit (B)

### PRIOR ART DOCUMENT

### Patent Document

[Patent document 1] International Publication WO 2011/052709

### SUMMARY OF THE INVENTION

### Problem to be Solved by the Invention

However, an organic photoelectric conversion device having an organic layer containing the above-described composition has not necessarily sufficient photoelectric conversion efficiency.

The present invention has an object of providing a composition which improves photoelectric conversion efficiency when used in an organic layer contained in an organic photoelectric conversion device.

### Means for Solving the Problem

That is, the present invention provides the following [1] to [18].

[1] A composition comprising a first compound, a second compound and a third compound, wherein the first compound is a polymer compound having a constitutional unit represented by the formula (1), the second compound is a polymer compound having a constituent unit represented by the formula (2) and the third compound is a compound different from the first compound and the second compound:

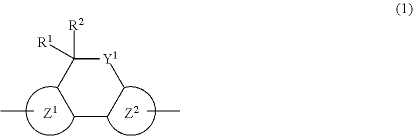

(wherein R¹ and R² represent each independently a hydrogen atom or a substituent. Y¹ represents an oxygen atom, a sulfur atom, —C(═O)— or —N(R⁵)—. R⁵ represents a hydrogen atom or a substituent. Ring Z¹ and ring Z² represent each independently an aromatic carbocyclic ring which may have a substituent or a heterocyclic ring which may have a substituent.)

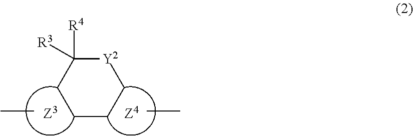

(wherein R³ and R⁴ represent each independently a hydrogen atom or a substituent, provided that R³ and R⁴ are different from R¹ and R². Y² represents an oxygen atom, a sulfur atom, —C(═O)— or —N(R²)—. R⁵ represents a hydrogen atom or a substituent. Ring Z³ and ring Z⁴ represent each independently an aromatic carbocyclic ring which may have a substituent or a heterocyclic ring which may have a substituent.).

[2] The composition according to [1], wherein Y¹ and Y² represent each independently an oxygen atom, a sulfur atom or —N(R²)—.

[3] The composition according to [1] or [2], wherein R¹ and R² are both a branched alkyl group, or R¹ and R² are both a linear alkyl group.

[4] The composition according to [1] or [2], wherein R¹ and R² are both a branched alkyl group.

[5] The composition according to any one of [1] to [4], wherein R³ and R⁴ are both a branched alkyl group, or R³ and R⁴ are both a linear alkyl group.

[6] The composition according to any one of [1] to [4], wherein R³ and R⁴ are both a linear alkyl group.

[7] The composition according to any one of [1] to [6], wherein R¹, R², R³ and R⁴ have each independently a number of carbon atoms of 10 to 15.

[8] The composition according to any one of [1] to [7], wherein at least one of the polymer compound having a constitutional unit represented by the formula (1) and the polymer compound having a constitutional unit represented by the formula (2) is a polymer compound further containing a constitutional unit represented by the formula (3):

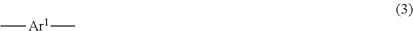

(wherein Ar¹ is different from the constitutional unit represented by the formula (1) and the constitutional unit represented by the formula (2) and represents an arylene group which may have a substituent or a divalent heterocyclic group which may have a substituent.).

[9] The composition according to [8], wherein Ar¹ is a constitutional unit represented by the formula (3-1), a constitutional unit represented by the formula (3-2), a constitutional unit represented by the formula (3-3), a constitutional unit represented by the formula (3-4), a constitutional unit represented by the formula (3-5), a constitutional unit represented by the formula (3-6), a constitutional unit represented by the formula (3-7) or a constitutional unit represented by the formula (3-8):

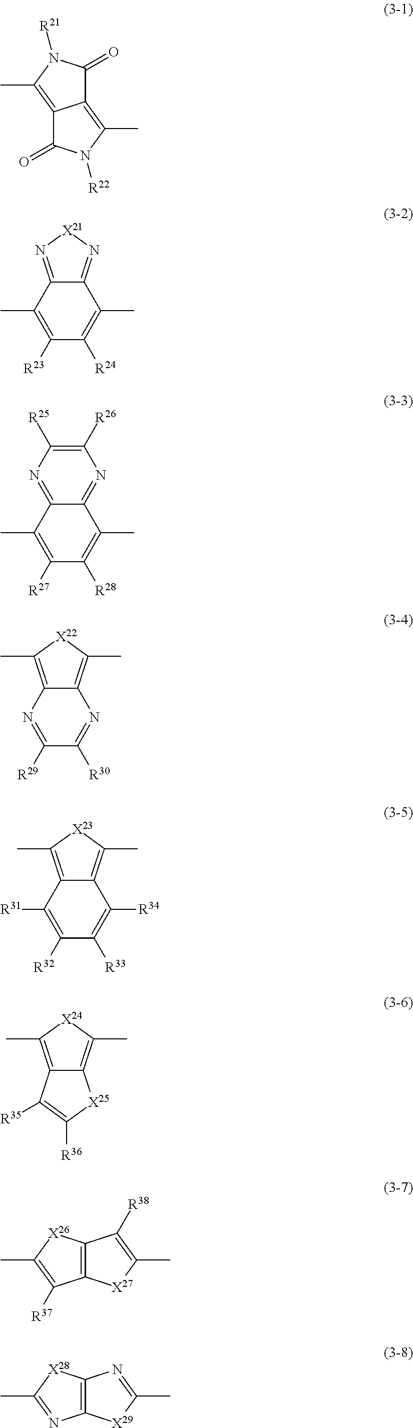

(in the formulae (3-1) to (3-8), R²¹, R²², R²³, R²⁴, R²⁵, R²⁶, R²⁷, R²⁸, R²⁹, R³⁰, R³¹, R³², R³³, R³⁴, R³⁵, R³⁶, R³⁷ and R³⁸ represent each independently a hydrogen atom or a substituent. X²¹, X²², X²³, X²⁴, X²⁵, X²⁶, X²⁷, X²⁸ and X²⁹ represent each independently a sulfur atom, an oxygen atom or a selenium atom.).

[10] The composition according to any one of [1] to [9], wherein third compound is an electron accepting compound.

[11] The composition according to [10], wherein the electron accepting compound is a fullerene or fullerene derivative.

[12] A film comprising the composition according to any one of [1] to [11]. [13] A liquid comprising the composition according to any one of [1] to [11] and a solvent.

[14] An electronic device comprising the composition according to any one of [1] to [11].

[15] An organic photoelectric conversion device having a first electrode and a second electrode, having an active layer between the first electrode and the second electrode, and comprising the composition according to any one of [1] to [11] in the active layer.

[16] A solar cell module comprising the organic photoelectric conversion device according to [15].

[17] An image sensor comprising the organic photoelectric conversion device according to [15].

[18] An organic film transistor having a gate electrode, a source electrode, a drain electrode and an active layer, and comprising the composition according to any one of [1] to [11] in the active layer.

### MODES FOR CARRYING OUT THE INVENTION

The present invention will be illustrated in detail below.

The composition of the present invention comprises a first compound, a second compound and a third compound, and the first compound is a polymer compound having a constitutional unit represented by the formula (1), the second compound is a polymer compound having a constitutional unit represented by the formula (2) and the third compound is a compound different from the first compound and the second compound.

In the formula (1), R¹ and R² represent each independently a hydrogen atom or a substituent. Specific examples of the substituent represented by R¹ and R² include a halogen atom, an alkyl group which may have a substituent, an alkoxy group which may have a substituent, an alkylthio group which may have a substituent, an aryl group which may have a substituent, an aryloxy group which may have a substituent, an arylthio group which may have a substituent, an arylalkyl group which may have a substituent, an arylalkoxy group which may have a substituent, an arylalkylthio group which may have a substituent, an acyl group, an acyloxy group, an amide group, an acid imide group, an imino group, an amino group, a substituted amino group, a substituted silyl group, a substituted silyloxy group, a substituted silylthio group, a substituted silylamino group, a heterocyclic group, a heterocyclicoxy group, a heterocyclicthio group, an arylalkenyl group which may have a substituent, an arylalkynyl group which may have a substituent, a carboxy group which may have a substituent, a nitro group and a cyano group.

The halogen atom represented by R¹ and R² includes a fluorine atom, a chlorine atom, a bromine atom and an iodine atom.

The alkyl group represented by R¹ and R² may be linear, branched or cyclic. The number of carbon atoms of the alkyl group is usually 1 to 30. The alkyl group may have a substituent. The substituent includes a halogen atom. Specific examples of the alkyl group which may have a substituent include linear alkyl groups such as a methyl group, an ethyl group, a propyl group, an isopropyl group, a butyl group, an isobutyl group, a sec-butyl group, a tert-butyl group, a pentyl group, an isopentyl group, a 2-methylbutyl group, a 1-methylbutyl group, a hexyl group, an isohexyl group, a 3-methylpentyl group, a 2-methylpentyl group, a 1-methylpentyl group, a heptyl group, an octyl group, an isooctyl group, a 2-ethylhexyl group, a 3-propylheptyl group, a 3,7-dimethyloctyl group, a nonyl group, a decyl group, an undecyl group, a dodecyl group, a 3-heptyldodecyl group, a tetradecyl group, a hexadecyl group, an octadecyl group, an eicosyl group and the like, and cycloalkyl groups such as a cyclopentyl group, a cyclohexyl group, an adamantyl group and the like.

The alkyl portion of the alkoxy group represented by R¹ and R² may be linear, branched or cyclic. The alkoxy group may have a substituent. The number of carbon atoms of the alkoxy group is usually 1 to 20. The substituent includes a halogen atom and an alkoxy group (for example, having a number of carbon atoms of 1 to 20). Specific examples of the alkoxy group which may have a substituent include a methoxy group, an ethoxy group, a propoxy group, an isopropoxy croup, a butoxy group, an isobutoxy group, a tert-butoxy group, a pentyloxy group, a hexyloxy group, a cyclohexyloxy group, a heptyloxy group, an octyloxy group, a 2-ethylhexyloxy group, a nonyloxy group, a decyloxy group, a 3,7-dimethyloctyloxy group, a lauryloxy group, a trifluoromethoxy group, a pentafluoroethoxy group, a perfluorobutoxy group, a perfluorohexyloxy group, a perfluorooctyloxy group, a methoxymethyloxy group and a 2-methoxyethyloxy group.

The alkyl portion of the alkylthio group represented by R¹ and R² may be linear, branched or cyclic. The alkylthio group may have a substituent. The number of carbon atoms of the alkylthio group is usually 1 to 20. The substituent includes a halogen atom. Specific examples of the alkylthio group which may have a substituent include a methylthio group, an ethylthio group, a propylthio group, an isopropylthio group, a butylthio group, an isobutylthio group, a tert-butylthio group, a pentylthio group, a hexylthio group, a cyclohexylthio group, a heptylthio group, an octylthio group, a 2-ethylhexylthio group, a nonylthio group, a decylthio group, a 3,7-dimethyloctylthio group, a laurylthio group and a trifluoromethylthio group.

The aryl group represented by R¹ and R² is one obtained by removing from an aromatic hydrocarbon one hydrogen atom on the aromatic ring. The number of carbon atoms of the aryl group is usually 6 to 60. The aryl group may have a substituent. The substituent includes a halogen atom and an alkoxy group (for example, having a number of carbon atoms of 1 to 20). Specific examples of the aryl group which may have a substituent include a phenyl group, a C1 to C12 alkoxyphenyl group (The C1 to C12 alkoxy denotes an alkoxy having a number of carbon atoms of 1 to 12. The C1 to C12 alkoxy is preferably a C1 to C8 alkoxy, more preferably a C1 to C6 alkoxy. The C1 to C8 alkoxy denotes an alkoxy having a number of carbon atoms of 1 to 8, and the C1 to C6 alkoxy denotes an alkoxy having a number of carbon atoms of 1 to 6. Specific examples of the C1 to C12 alkoxy, the C1 to C8 alkoxy and the C1 to C6 alkoxy include the same groups as the alkoxy group represented by R¹ and R² explained and exemplified above. The same shall apply hereinafter.), a C1 to C12 alkylphenyl group (The C1 to C12 alkyl denotes an alkyl having a number of carbon atoms of 1 to 12. The C1 to C12 alkyl is preferably a C1 to C8 alkyl, more preferably a C1 to C6 alkyl. The C1 to C8 alkyl denotes an alkyl having a number of carbon atoms of 1 to 8, and the C1 to C6 alkyl denotes an alkyl having a number of carbon atoms of 1 to 6. Specific examples of the C1 to C12 alkyl, the C1 to C8 alkyl and the C1 to C6 alkyl include the same groups as the alkyl group represented by R¹ and R² explained and exemplified above. The same shall apply hereinafter.), a 1-naphthyl group, a 2-naphthyl group and a pentafluorophenyl group. The number of carbon atoms of the aryloxy group represented by R¹ and R² is usually 6 to 60, and the aryl portion may have a substituent. The substituent includes a halogen atom and an alkoxy group (for example, having a number of carbon atoms of 1 to 20). Specific examples of the aryloxy group which may have a substituent include a phenoxy group, a C1 to C12 alkoxyphenoxy group, a C1 to C12 alkylphenoxy group, a 1-naphthyloxy group, a 2-naphthyloxy group and a pentafluorophenyloxy group.

The number of carbon atoms of the arylthio group represented by R¹ and R² is usually 6 to 60, and the aryl portion may have a substituent. The substituent includes a halogen atom and an alkoxy group (for example, having a number of carbon atoms of 1 to 20). Specific examples of the arylthio group which may have a substituent include a phenylthio group, a C1 to C12 alkoxyphenylthio group, a C1 to C12 alkylphenylthio group, a 1-naphthylthio group, a 2-naphthylthio group and a pentafluorophenylthio group.

The number of carbon atoms of the arylalkyl group represented by R¹ and R² is usually 7 to 60, and the aryl portion may have a substituent. The substituent includes a halogen atom and an alkoxy group (for example, having a number of carbon atoms of 1 to 20). Specific examples of the arylalkyl group which may have a substituent include a phenyl-C1 to C12 alkyl group, a C1 to C12 alkoxyphenyl-C1 to C12 alkyl group, a C1 to C12 alkylphenyl-C1 to C12 alkyl group, a 1-naphthyl-C1 to C12 alkyl group and a 2-naphthyl-C1 to C12 alkyl group.

The number of carbon atoms of the arylalkoxy group represented by R¹ and R² is usually 7 to 60, and the aryl portion may have a substituent. The substituent includes a halogen atom and an alkoxy group (for example, having a number of carbon atoms of 1 to 20). Specific examples of the arylalkoxy group which may have a substituent include a phenyl-C1 to C12 alkoxy group, a C1 to C12 alkoxyphenyl-C1 to C12 alkoxy group, a C1 to C12 alkylphenyl-C1 to C12 alkoxy group, a 1-naphthyl-C1 to C12 alkoxy group and a 2-naphthyl-C1 to C12 alkoxy group.

The number of carbon atoms of the arylalkylthio group represented by R¹ and R² is usually 7 to 60, and the aryl portion may have a substituent. The substituent includes a halogen atom and an alkoxy group (for example, having a number of carbon atoms of 1 to 20). Specific examples of the arylalkylthio group which may have a substituent include a phenyl-C1 to C12 alkylthio group, a C1 to C12 alkoxyphenyl-C1 to C12 alkylthio group, a C1 to C12 alkylphenyl-C1 to C12 alkylthio group, a 1-naphthyl-C1 to C12 alkylthio group and a 2-naphthyl-C1 to C12 alkylthio group.

The acyl group represented by R¹ and R² is one obtained by removing a hydroxyl group in a carboxylic acid. The number of carbon atoms of the acyl group is usually 2 to 20. Specific examples of the acyl group include alkylcarbonyl groups having a number of carbon atoms of 2 to 20 which may be substituted with a halogen such as an acetyl group, a propionyl group, a butylyl group, an isobutylyl group, a pivaloyl group, a trifluoroacetyl group and the like, and phenylcarbonyl groups which may be substituted with a halogen such as a benzoyl group, a pentafluorobenzoyl group and the like.

The acyloxy group represented by R¹ and R² is one obtained by removing a hydrogen atom in a carboxylic acid. The number of carbon atoms of the acyloxy group is usually 2 to 20. Specific examples of the acyloxy group include an acetoxy group, a propionyloxy group, a butylyloxy group, an isobutylyloxy group, a pivaloyloxy group, a benzoyloxy group, a trifluoroacetyloxy group and a pentafluorobenzoyloxy group.

The amide group represented by R¹ and R² is one obtained by removing from an amide one hydrogen atom linked to the nitrogen atom. The number of carbon atoms of the amide group is usually 1 to 20. Specific examples of the amide group include a formamide group, an acetamide group, a propioamide group, a butyroamide group, a benzamide group, a trifluoroacetamide group, a pentafluorobenzamide group, a diformamide group, a diacetamide group, a dipropioamide group, a dibutyroamide group, a dibenzamide group, a ditrifluoroacetamide group and a dipentafluorobenzamide group.

The imide group represented by R¹ and R² is one obtained by removing from an imide (—CO—NH—CO—) one hydrogen atom linked to the nitrogen atom. Specific examples of the imide group include a succinimide group and a phthalimide group.

The substituted amino group represented by R¹ and R² is one obtained by substituting one or two hydrogen atoms of an amino group. The substituent of the substituted amino group is, for example, an alkyl group which may have a substituent or an aryl group which may have a substituent. The definition and specific examples of the alkyl group which may have a substituent and the aryl group which may have a substituent are the same as the definition and specific examples of the alkyl group which may have a substituent and the aryl group which may have a substituent represented by R¹ and R². The number of carbon atoms of the substituted amino group is usually 1 to 40. Specific examples of the substituted amino group include a methylamino group, a dimethylamino group, an ethylamino group, a diethylamino group, a propylamino group, a dipropylamino group, an isopropylamino group, a diisopropylamino group, a butylamino group, an isobutylamino group, a tert-butylamino group, a pentylamino group, a hexylamino group, a cyclohexylamino group, a heptylamino group, an octylamino group, a 2-ethylhexylamino group, a nonylamino group, a decylamino group, a 3,7-dimethyloctylamino group, a laurylamino group, a cyclopentylamino group, a dicyclopentylamino group, a cyclohexylamino group, a dicyclohexylamino group, a pyrrolidyl group, a piperidyl group, a ditrifluoromethylamino group, a phenylamino group, a diphenylamino group, a C1 to C12 alkyloxyphenylamino group, a di(C1 to C12 alkoxyphenyl)amino group, a di(C1 to C12 alkylphenyl)amino group, a 1-naphthylamino group, a 2-naphthylamino group, a pentafluorophenylamino group, a pyridylamino group, a pyridazinylamino group, a pyrimidylamino group, a pyrazylamino group, a triazylamino group, a phenyl-C1 to C12 alkylamino group, a C1 to C12 alkoxyphenyl-C1 to C12 alkylamino group, a C1 to C12 alkylphenyl-C1 to C12 alkylamino group, a di(C1 to C12 alkoxyphenyl-C1 to C12 alkylamino group, a di(C1 to C12 alkylphenyl-C1 to C12 alkylamino group, a 1-naphthyl-C1 to C12 alkylamino group and a 2-naphthyl-C1 to C12 alkylamino group.

The substituted silyl group represented by R¹ and R² is one obtained by substituting one, two or three hydrogen atoms of a silyl group, and generally one obtained by substituting all three hydrogen atoms of a silyl group. Specific examples of the substituent of the substituted silyl group include an alkyl group which may have a substituent and an aryl group which may have a substituent. The definition and specific examples of the alkyl group which may have a substituent and the aryl group which may have a substituent are the same as the definition and specific examples of the alkyl group which may have a substituent and the aryl group which may have a substituent represented by R¹ and R². Specific examples of the substituted silyl group include a trimethylsilyl group, a triethylsilyl group, a tripropylsilyl group, a triisopropylsilvl group, a tert-butyldimethylsilyl group, a triphenylsilyl group, a tri-p-xylylsilyl group, a tribenzylsilyl group, a diphenylmethylsilyl group, a tert-butyldiphenylsilyl group and a dimethylphenylsilyl group.

The substituted silyloxy group represented by R¹ and R² is one obtained by linking an oxygen atom to the above-described substituted silyl group. Specific examples of the substituted silyloxy group include a trimethylsilyloxy group, a triethylsilyloxy group, a tripropylsilyloxy group, a triisopropylsilyloxy group, a tert-butyldimethylsilyloxy group, a triphenylsilyloxy group, a tri-p-xylylsilyloxy group, a tribenzylsilyloxy group, a diphenylmethylsilyloxy group, a tert-butyldiphenylsilyloxy group and a dimethylphenylsilyloxy group.

The substituted silylthio group represented by R¹ and R² is one obtained by linking a sulfur atom to the above-described substituted silyl group. Specific examples of the substituted silylthio group include a trimethylsilylthio group, a triethylsilylthio group, a tripropylsilylthio group, a triisopropyisilylthio group, a tert-butyldimethylsilylthio group, a triphenylsilylthio group, a tri-p-xylylsilylthic group, a tribenzylsilylthio group, a diphenylmethylsilylthio group, a tert-butyldiphenvlsilylthio group and a dimethylphenylsilylthio group.

The substituted silylamino group represented by R¹ and R² is one obtained by substituting one or two hydrogen atoms of an amino group with the above-described substituted silyl group. Specific examples of the substituted silylamino group include a trimethylsilylamino group, a triethylsilylamino group, a tripropylsilylamino group, a triisopropylsilylamino group, a tert-butyldimethylsilylamino group, a triphenylsilylamino group, a tri-p-xylyisilylamino group, a tribenzylsilylamino group, a diphenylmethylsilylamino group, a tert-butyldiphenylsilylamino group, a dimethylphenylsilylamino group, a di(trimethylsilyl)amino group, a di(triethylsilyl)amino group, a di(tripropylsilyl)amino group, a di(triisopropylsilyl)amino group, a di(tert-butyldimethylsilyl)amino group, a di(triphenylsilyl)amino group, a di(tri-p-xylylsilyl)amino group, a di(tribenzylsilyl)amino group, a di(diphenylmethylsilyl)amino group, a di(tert-butyldiphenylsilyl)amino group and a di(dimethylphenylsilyl)amino group.

The heterocyclic group represented by R¹ and R² is one obtained by removing one hydrogen atom from a heterocyclic compound such as furan, thiophene, pyrrole, pyrroline, pyrrolidine, oxazole, isooxazole, triazole, isothiazole, imidazole, imidazoline, imidazolidine, pyrazole, pyrazoline, pyrazolidine, furazan, triazole, thiadiazole, oxadiazole, tetrazole, pyran, pyridine, piperidine, thiopyran, pyridazine, pyrimidine, pyrazine, piperazine, morpholine, triazine, benzofuran, isobenzofuran, benzothiophene, indole, isoindole, indolizine, indoline, isoindoline, chromene, chromane, isochromane, benzopyran, quinoline, isoquinoline, quinolizine, benzoimidazole, benzothiazole, indazole, naphthyridine, quinoxaline, quinazoline, quinazolidine, cinnoline, phthalazine, purine, pteridine, carbazole, xanthene, phenanthridine, acridine, β-carboline, perimidine, phenanthroline, thianthrene, phenoxathiin, phenoxazine, phenothiazine, phenazine and the like which may have a substituent. Specific examples of the substituent include a halogen atom, an alkyl group which may have a substituent, an alkoxy group which may have a substituent, an alkylthio group which may have a substituent and an aryl group which may have a substituent. The definition and specific examples of the halogen atom, the alkyl group which may have a substituent, the alkoxy group which may have a substituent, the alkylthio group which may have a substituent and the aryl group which may have a substituent are the same as the definition and specific examples of the halogen atom, the alkyl group which may have a substituent, the alkoxy group which may have a substituent, the alkylthio group which may have a substituent and the aryl group which may have a substituent represented by R¹ and R². The heterocyclic group is preferably an aromatic heterocyclic group.

The heterocyclicoxy group represented by R¹ and R² includes a group represented by the formula (4) obtained by linking an oxygen atom to the above-described heterocyclic group.

The heterocyclicthio group represented by R¹ and R² includes a group represented by the formula (5) obtained by linking a sulfur atom to the above-described heterocyclic group.

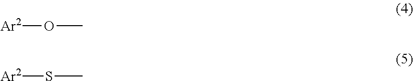

(in the formula (4) and the formula (5), Ar² represents a heterocyclic group.)

The number of carbon atoms of the heterocyclicoxy group is usually 2 to 60. Specific examples of the heterocyclicoxy group include a thienyloxy group, a C1 to C12 alkylthienyloxy group, a pyrrolyloxy group, a furyloxy group, a pyridyloxy group, a C1 to C12 alkylpyridyloxy group, an imidazolyloxy group, a pyrazolyloxy group, a triazolyloxy group, an oxazolyloxy group, a thiazoleoxy group and a thiadiazoleoxy group.

The number of carbon atoms of the heterocyclicthio group is usually 2 to 60. Specific examples of the heterocyclicthio group include a thienylmercapto group, a C1 to C12 alkylthienylmercapto group, a pyrrolylmercapto group, a furylmercapto group, a pyridylmercapto group, a C1 to C12 alkylpyridylmercapto group, an imidazolylmercapto group, a pyrazolylmercapto group, a triazolylmercapto group, an oxazolylmercapto group, a thiazolemercapto group and a thiadiazclemercapto group.

The number of carbon atoms of the arylalkenyl group represented by R¹ and R² is usually 8 to 20, and the aryl portion may have a substituent. The substituent includes a halogen atom and an alkoxy group (for example, having a number of carbon atoms of 1 to 20). Specific examples of the arylalkenyl group include a styryl group.

The number of carbon atoms of the arylalkynyl group represented by R¹ and R² is usually 8 to 20, and the aryl portion may have a substituent. The substituent includes a halogen atom and an alkoxy group (for example, having a number of carbon atoms of 1 to 20). Specific examples of the arylalkynyl group include a phenylacetylenyl group.

The hydrogen atom in the carboxy group represented by R¹ and R² may be substituted with a substituent. The substituent includes an alkyl group having a number of carbon atoms of 1 to 20. Specific examples of the carboxy group include a methoxycarbonyl group, an ethoxycarbonyl group and a propcxycarbonyl group.

In the formula (1), Y¹ represents an oxygen atom, a sulfur atom, —C(═O)— or —N(R⁵)—. R⁵ represents a hydrogen atom or a substituent. The definition and specific examples of the substituent represented by R⁵ are the same as the definition and specific examples of the substituent represented by R¹ and R².

In the formula (1), ring Z¹ and ring Z² represent each independently an aromatic carbocyclic ring which may have a substituent or a heterocyclic ring which may have a substituent.

Specific examples of the aromatic carbocyclic ring represented by ring Z¹ and ring Z² include a benzene ring, a naphthalene ring, an anthracene ring, a phenanthrene ring, a pyrene ring, a perylene ring, a tetracene ring and a pentacene ring. The aromatic carbocyclic ring is preferably a benzene ring or a naphthalene ring, more preferably a benzene ring from the standpoint of improvement of photoelectric conversion efficiency of a photoelectric conversion device containing the composition of the present invention.

Specific examples of the heterocyclic ring represented by ring Z¹ and ring Z² include a pyridine ring, a pyrimidine ring, a pyridazine ring, a pyrazine ring, a quinoline ring, an isoquinoline ring, a quinoxaline ring, a quinazoline ring, an acridine ring, a phenanthroline ring, a thiophene ring, a benzothiophene ring, a dibenzothiophene ring, a furan ring, a benzofuran ring, a dibenzofuran ring, a pyrrole ring, an indole ring, a dibenzopyrrole ring, a silole ring, a benzosilole ring, a dibenzosilole ring, a borole ring, a benzoborole ring and a dibenzoborole ring. The sulfur atom in a thiophene ring, a benzothiophene ring and a dibenzothiophene ring may form a ring-shaped sulfoxide or a ring-shaped sulfone by linking of an oxo group. The heterocyclic ring represented by a ring Z¹ and a ring Z² is preferably an aromatic heterocyclic ring. The aromatic heterocyclic ring is preferably a thiophene ring, a furan ring or a pyrrole ring, more preferably a thiophene ring or a furan ring, particularly preferably a thiophene ring from the standpoint of improvement of photoelectric conversion efficiency of a photoelectric conversion device containing the composition of the present invention.

The definition and specific examples of the substituent which the aromatic carbocyclic ring and the heterocyclic ring represented by ring Z and ring Z² may have are the same as the definition and specific examples of the substituent represented by R¹ and R².

Specific examples of the constitutional unit represented by the formula (1) include constitutional units represented by the formulae (301) to (375) and constitutional units obtained by substituting a hydrogen atom on an aromatic carbocyclic ring or a heterocyclic ring contained in constitutional units represented by the formulae (301) to (375) with a substituent.

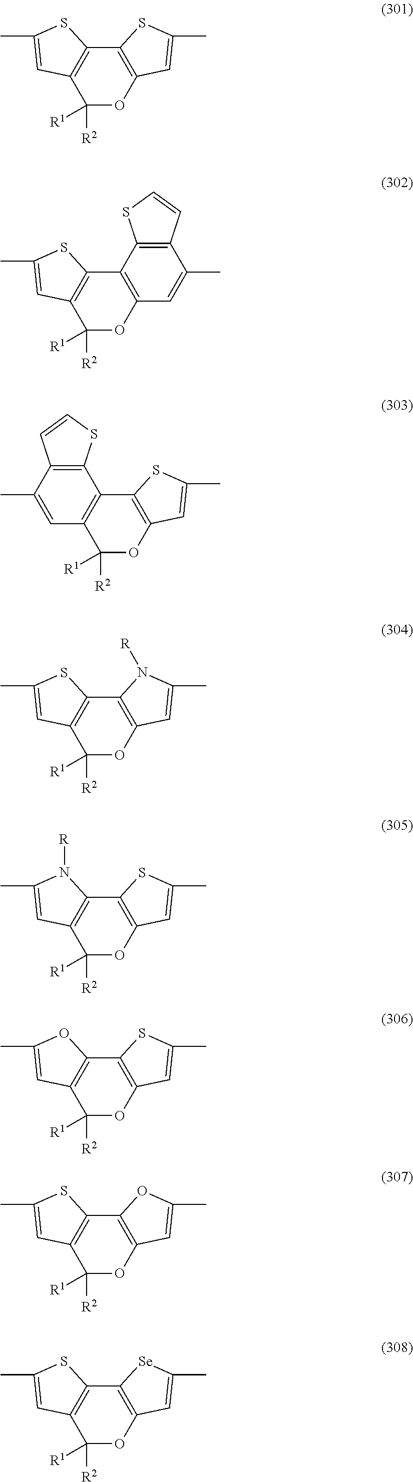

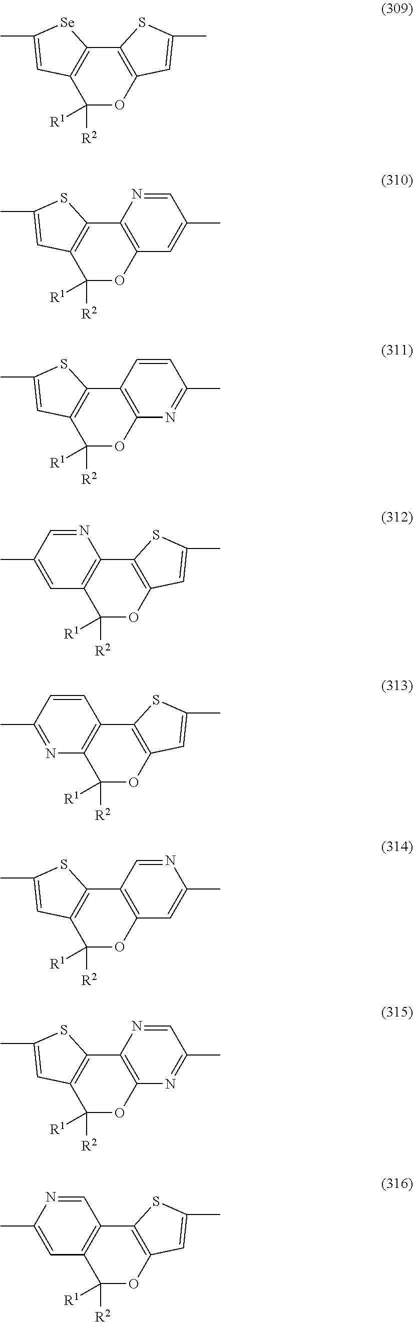

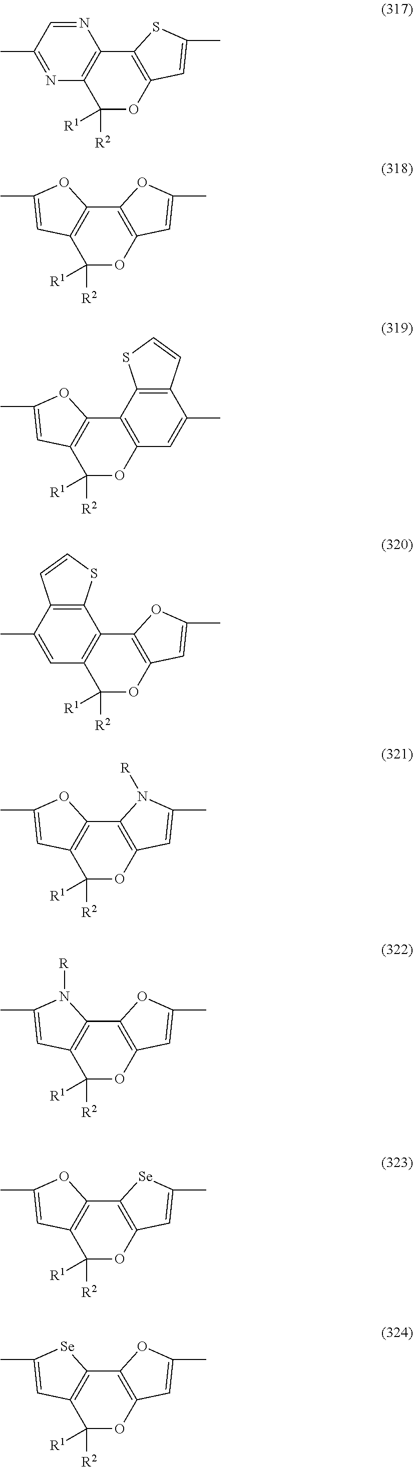

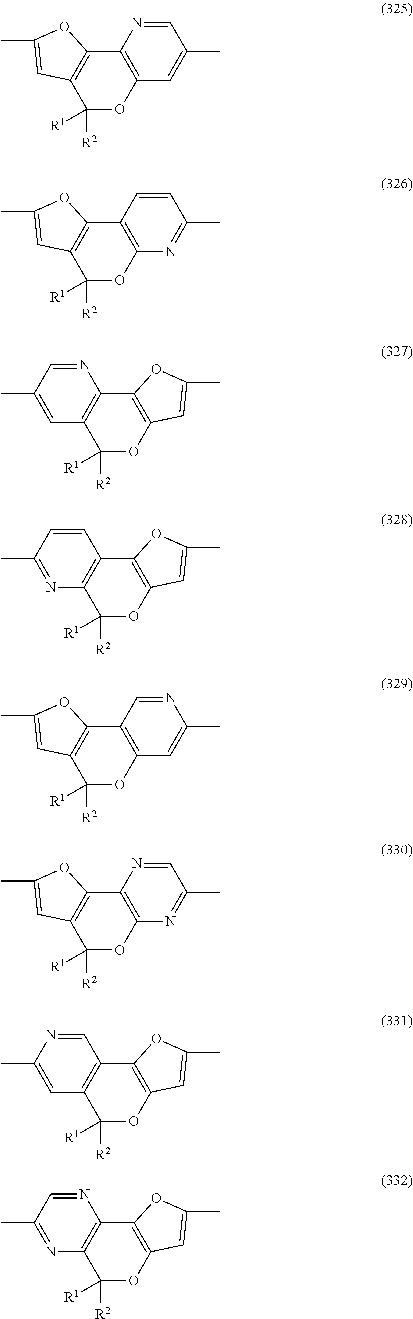

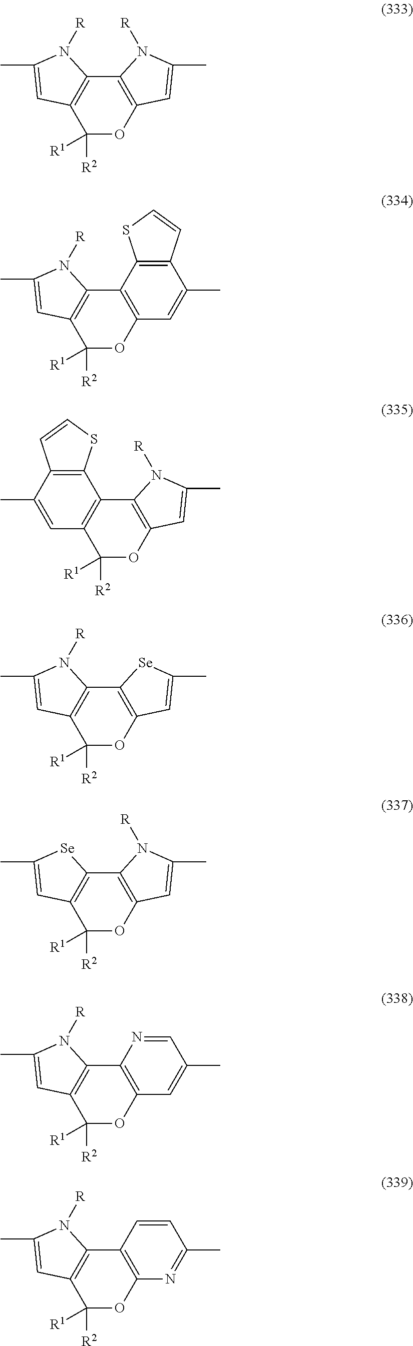

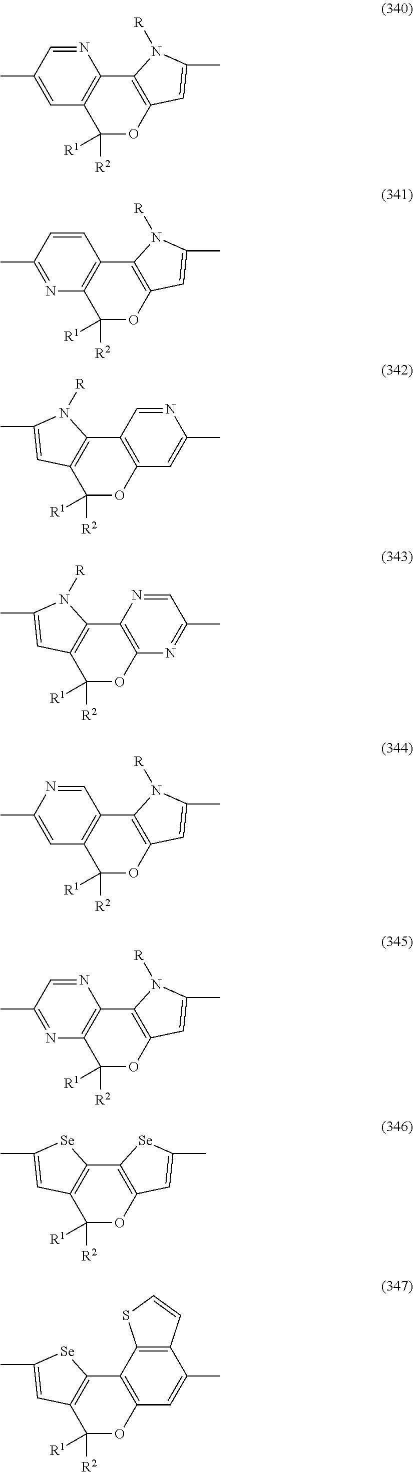

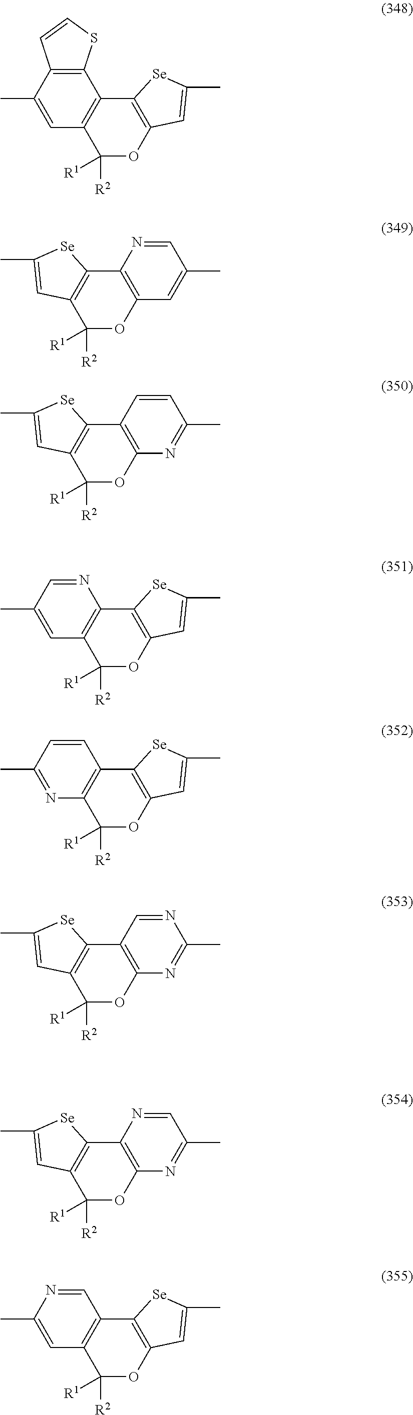

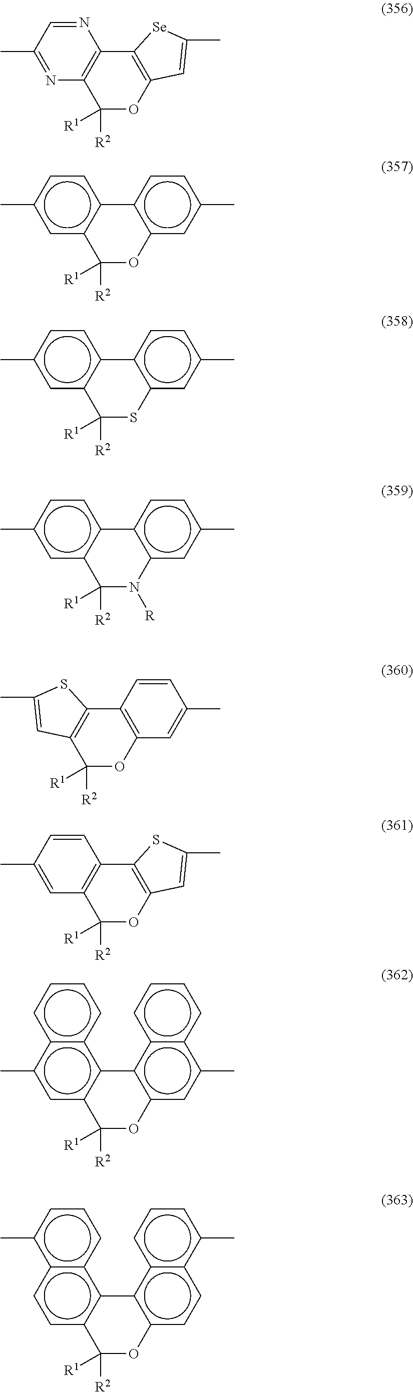

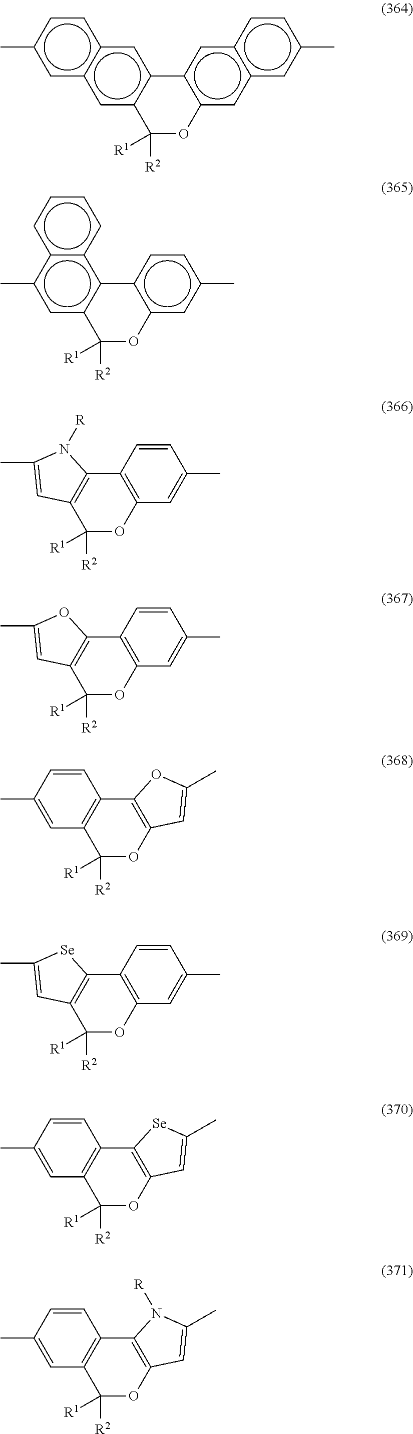

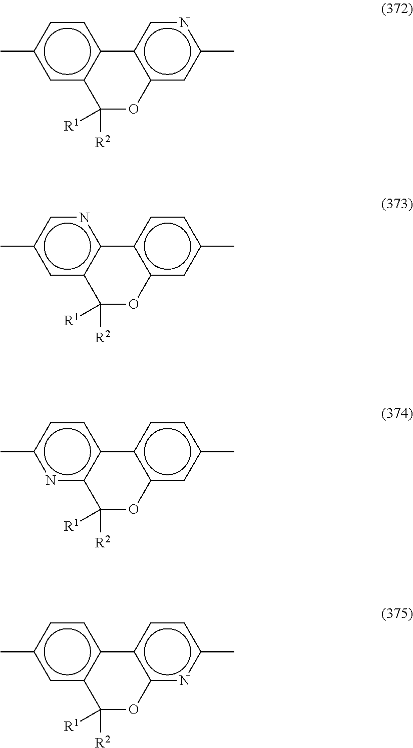

In the formulae (301) to [symbol] (375), R¹ and R² represent the same meaning as described above. R represents a hydrogen atom or a substituent. The definition and specific examples of the substituent represented by R are the same as the definition and specific examples of the substituent represented by R¹ and R².

In the (2), R³ and R⁴ represent each independently a hydrogen atom or a substituent, provided that R³ and R⁴ are different from R¹ and R². The definition and specific examples of the substituent represented by R³ and R⁴ are the same as the definition and specific examples of the substituent represented by R¹ and R².

In the formula (2), Y² represents an oxygen atom, a sulfur atom, —C(═O)— or —N(R⁵)—.

In the formula (2), ring Z³ and ring Z⁴ represent each independently an aromatic carbocyclic ring which may have a substituent or a heterocyclic ring which may have a substituent. The definition and specific examples of the aromatic carbocyclic ring and the heterocyclic ring represented by ring Z³ and ring Z⁴ are the same as the definition and specific examples of the aromatic carbocyclic ring and the heterocyclic ring represented by ring Z¹ and ring Z². The definition and specific examples of the substituent which the aromatic carbocyclic ring and the heterocyclic ring represented by ring Z³ and ring Z⁴ may have are the same as the definition and specific examples of the substituent represented by R¹ and R².

It is preferable that the aromatic carbocyclic ring and the heterocyclic ring represented by ring Z¹ and ring Z² have one or more substituents selected from the group consisting of an alkyl group which may have a substituent, an alkoxy group which may have a substituent, an aryloxy group which may have a substituent and an aryl group which may have a substituent from the standpoint of enhancement of solubility of the first compound and the second compound in an organic solvent.

Specific examples of the constitutional unit represented by the formula (2) include constitutional units represented by the formulae (401) to (475) and constitutional units obtained by substituting a hydrogen atom on an aromatic carbocyclic ring or a heterocyclic ring contained in constitutional units represented by the formulae (401) to (475) with a substituent.

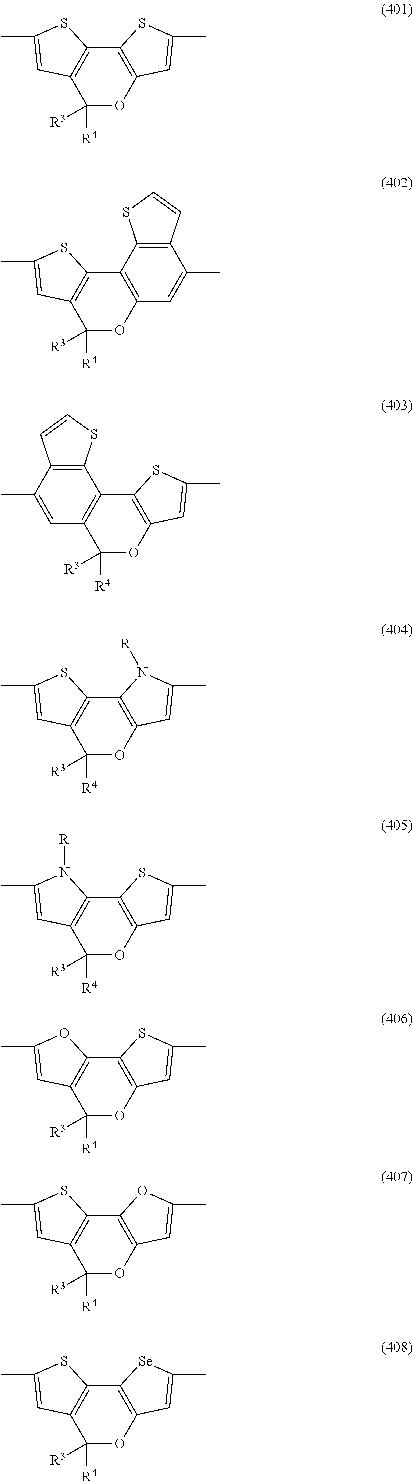

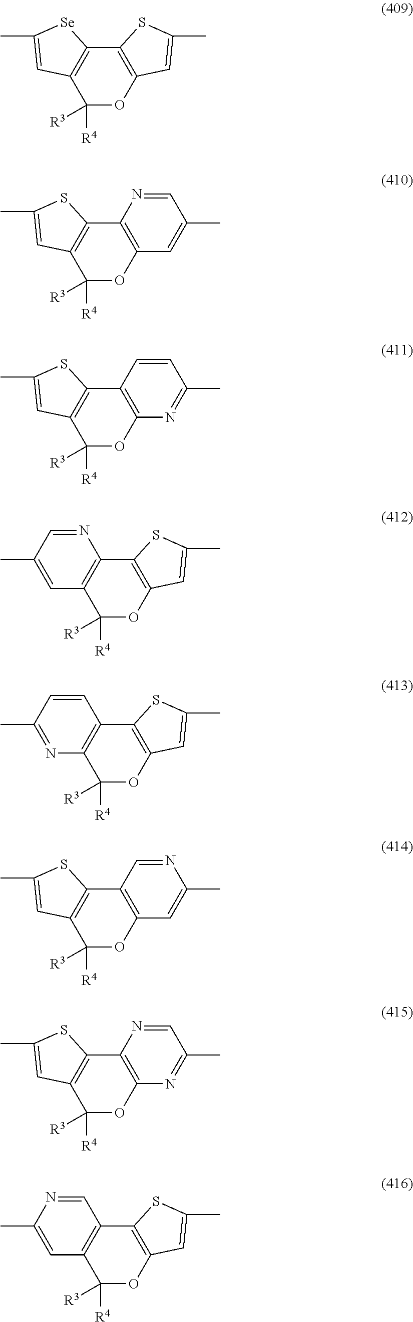

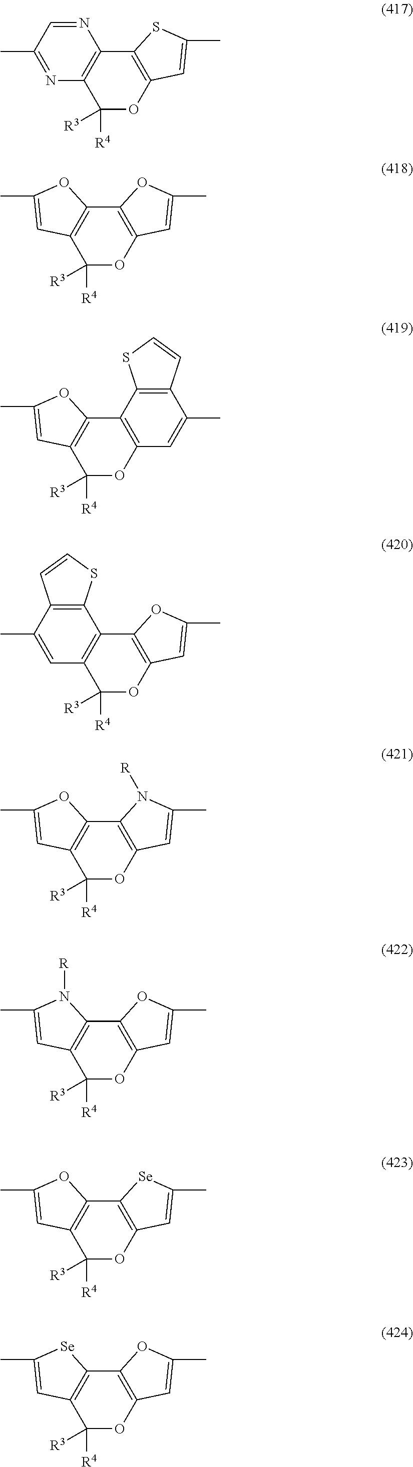

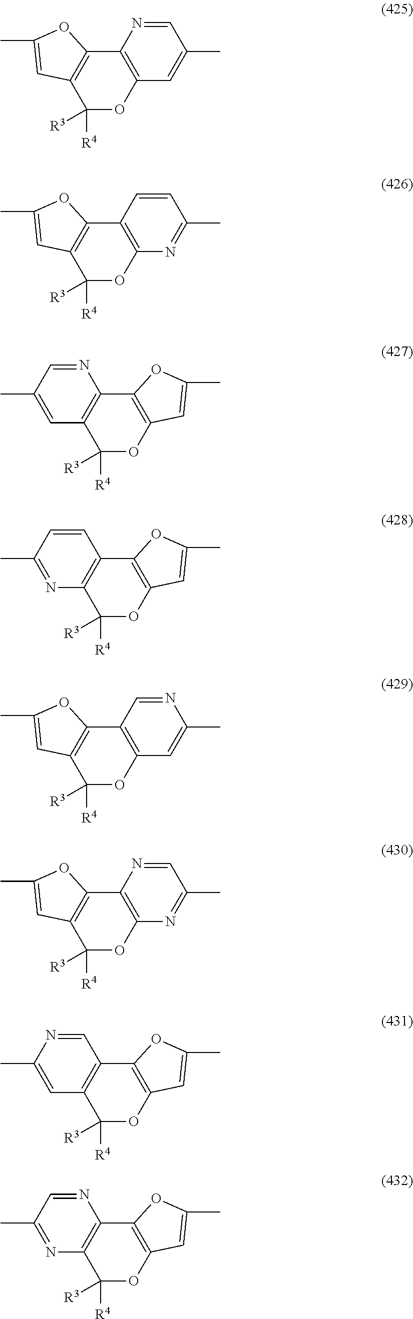

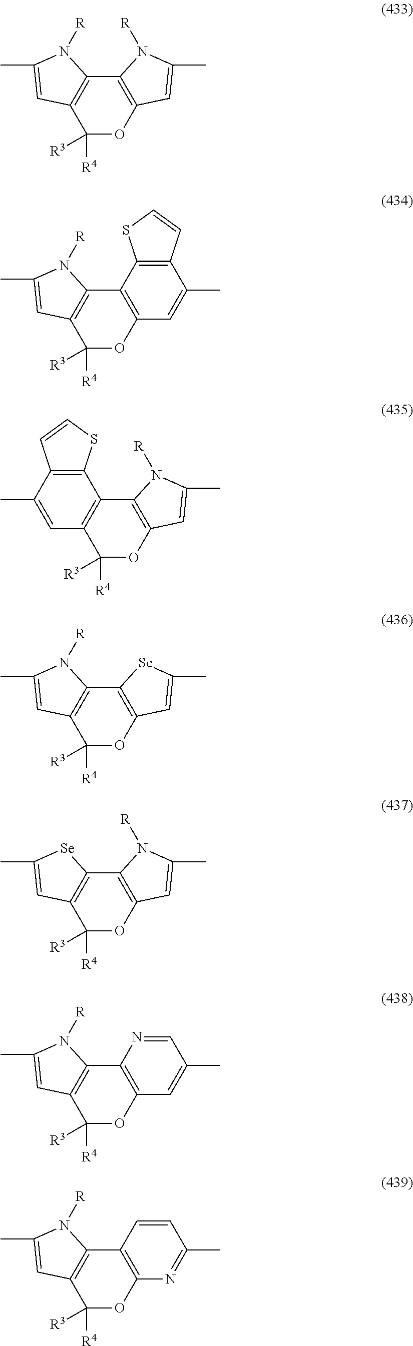

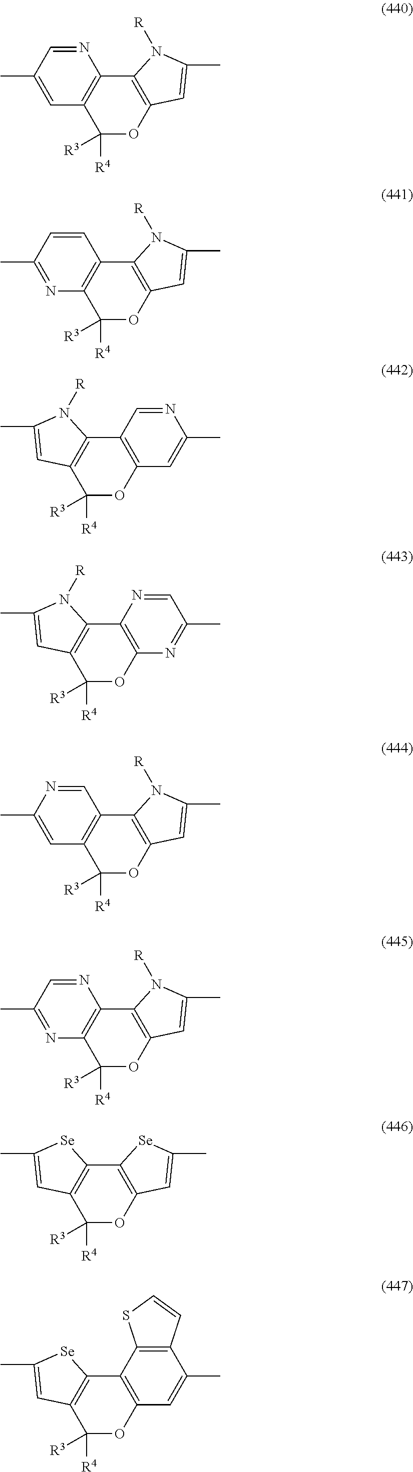

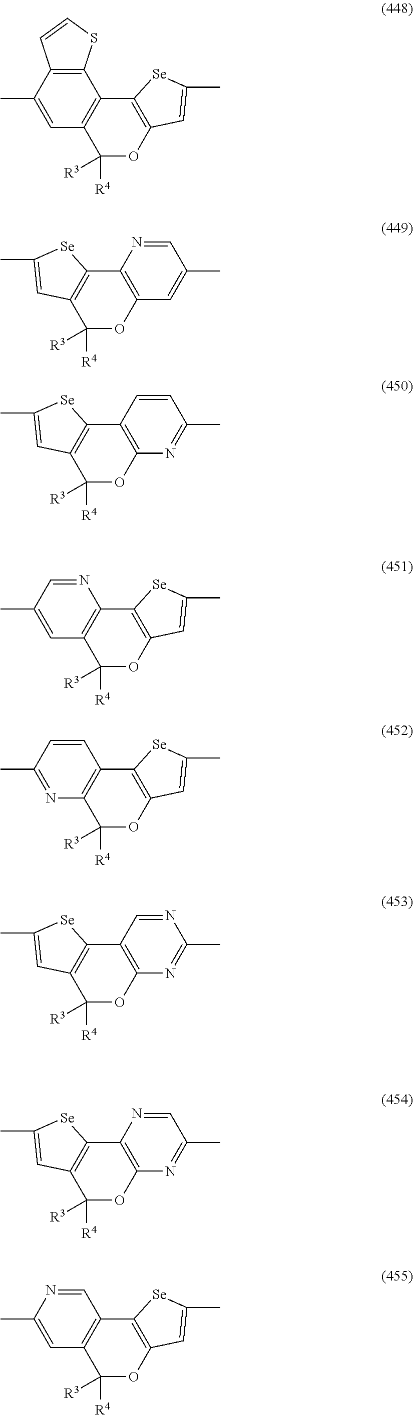

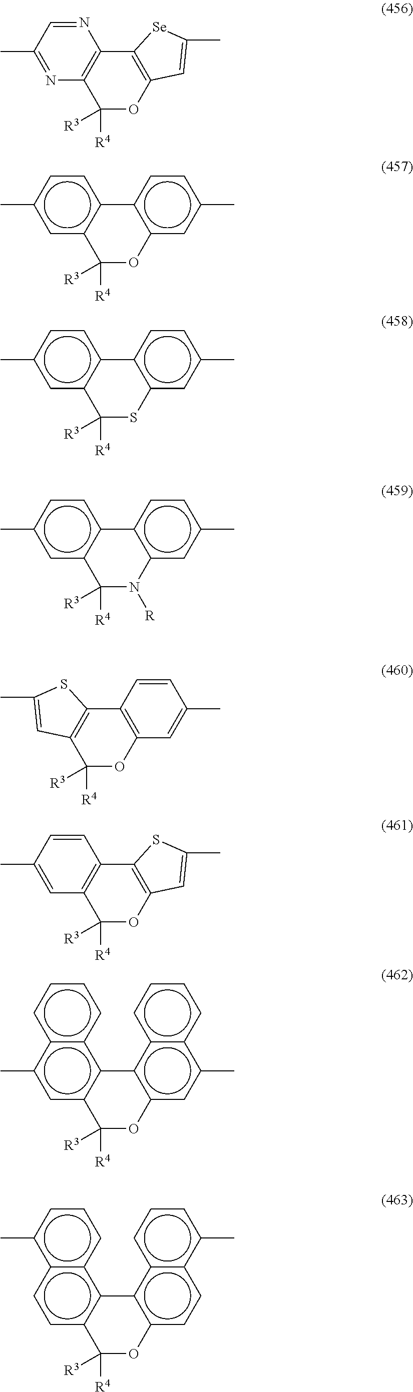

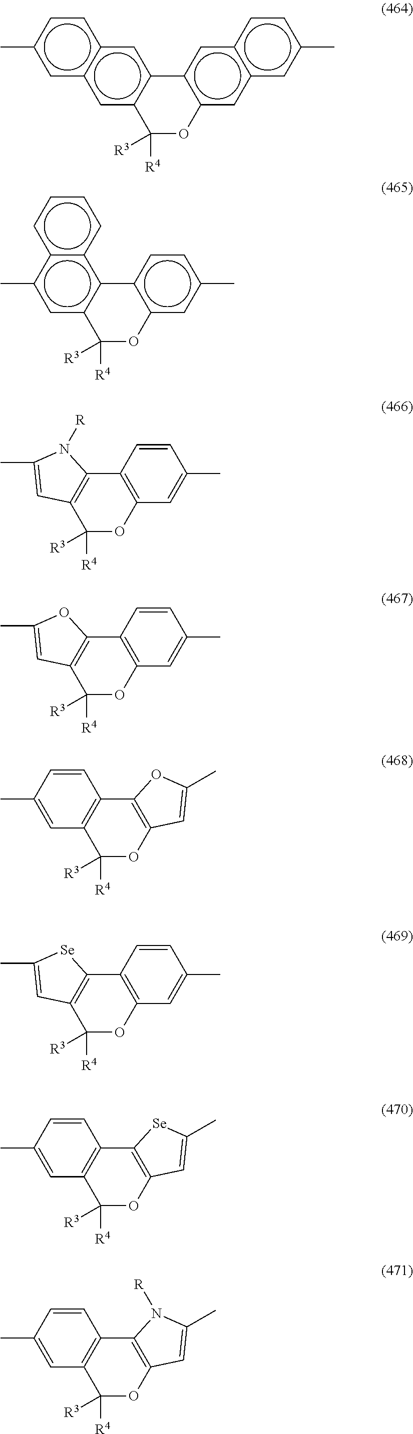

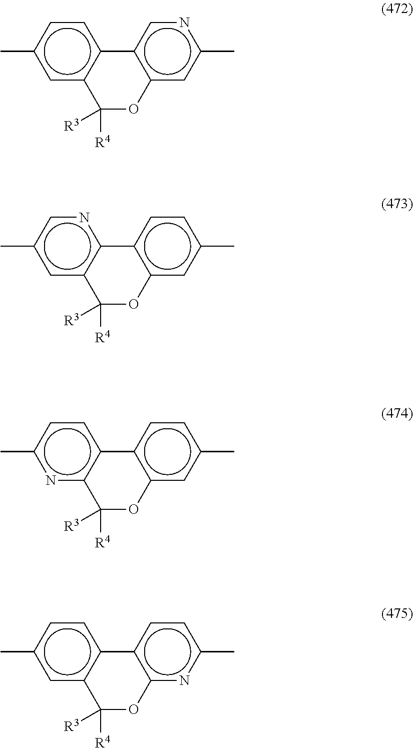

In the formulae (401) to (475), R³, R⁴ and R represent the same meaning as described above.

R¹, R², R³ and R⁴ represent preferably an alkyl group, an alkoxy group, an aryl group, an aryloxy group, an arylalkyl group or an arylalkoxy group, more preferably an alkyl group, an aryl group or an arylalkyl group, further preferably an alkyl group.

R¹ and R² represent preferably a branched alkyl group, and R³ and R⁴ represent preferably a linear alkyl group from the standpoint of enhancement of photoelectric conversion efficiency of an organic photoelectric conversion device containing the composition of the present invention.

The constitutional unit represented by the formula (1) in which R¹ and R² are a branched alkyl group includes, for example, constitutional units represented by the formulae (1-1) to (1-12).

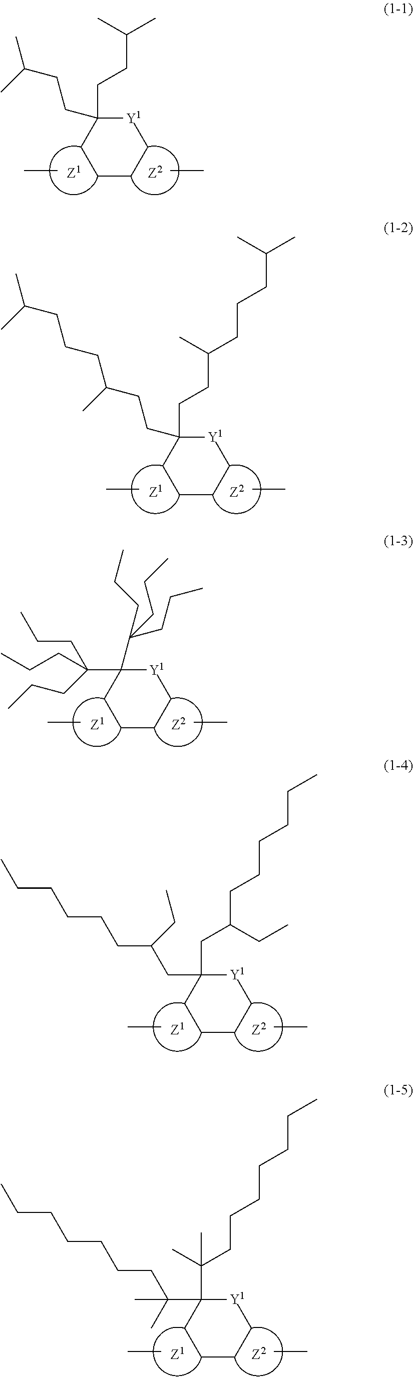

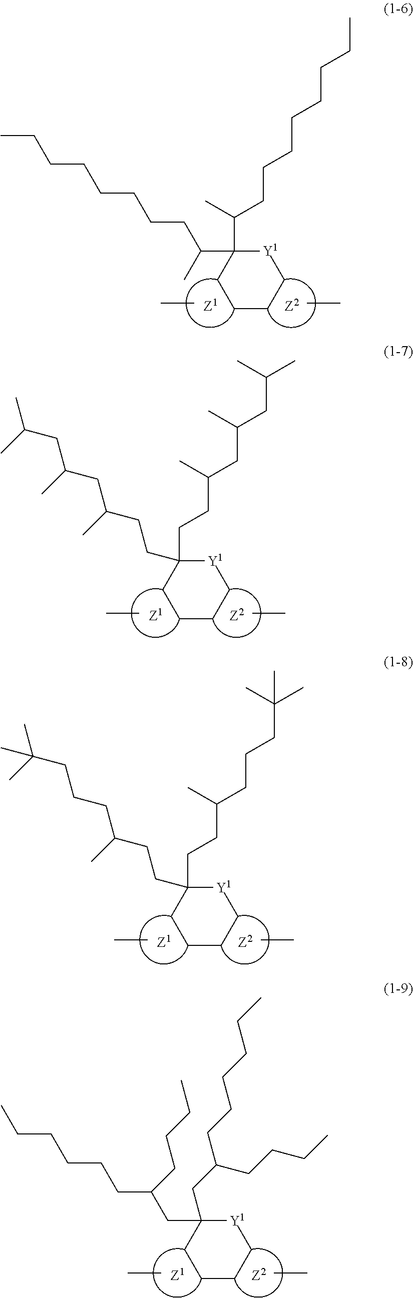

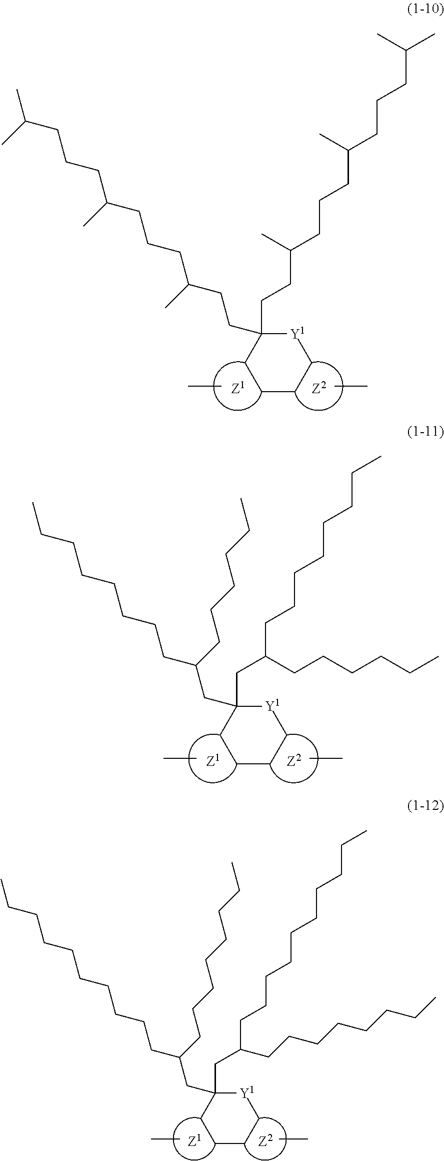

The number of carbon atoms of R¹ and R² is preferably 5 to 20, more preferably 8 to 16, further preferably 10 to 15. Of constitutional units represented by the formulae (1-1) to (1-12), preferable are constitutional units represented by the formulae (1-2) to (1-10).

The constitutional unit represented by the formula (2) in which R³ and R⁴ are a linear alkyl group includes, for example, constitutional units represented by the formulae (2-1) to (2-8).

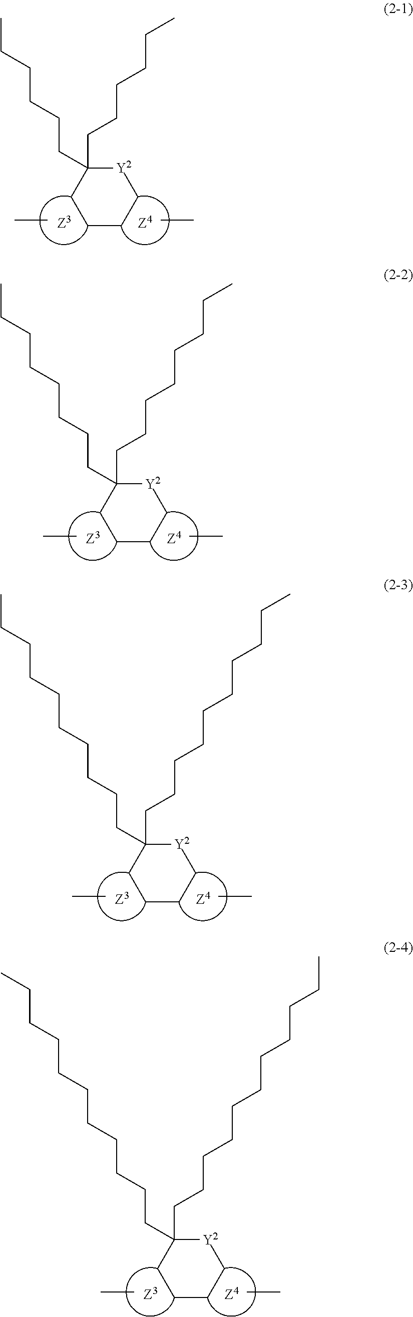

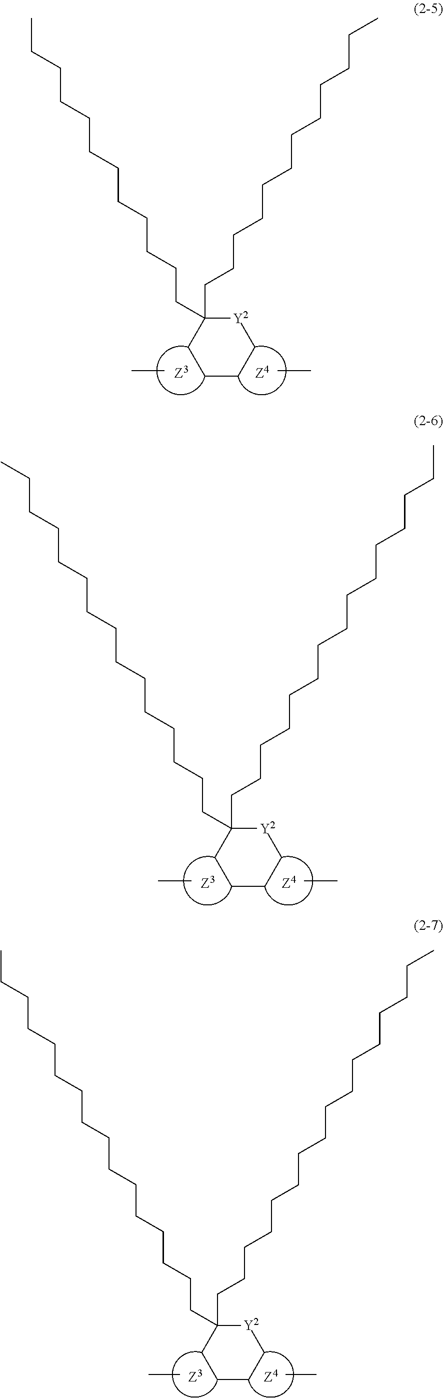

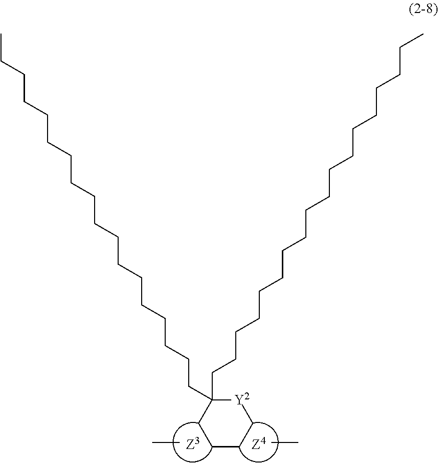

The number of carbon atoms of R³ and R⁴ is preferably 6 to 20, more preferably 8 to 16, further preferably 10 to 15. Of constitutional units represented by the formulae (2-1) to (2-8), preferable are constitutional units represented by the formulae (2-3) to (2-5).

The first compound and the second compound may have other constitutional units than the constitutional unit represented by the formula (1) and the constitutional unit represented by the formula (2). The other constitutional unit includes, for example, a constitutional unit represented by the formula (3).

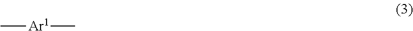

In the formula (3), Ar¹ is different from the constitutional unit represented by the formula (1) and represents an arylene group which may have a substituent or a divalent heterocyclic group.

The arylene group represented by Ar¹ is one obtained by removing from an aromatic hydrocarbon two hydrogen atoms on the aromatic ring. The number of carbon atoms of the arylene group is usually 6 to 60. The arylene group may have a substituent. The substituent includes a halogen atom and an alkoxy group (for example, having a number of carbon atoms of 1 to 20).

Specific examples of the arylene group which may have a substituent include a phenylene group which may have a substituent (the following formulae 1 to 3), a naphthalenediyl group which may have a substituent (the following formulae 4 to 13), an anthracenediyl group which may have a substituent (the following formulae 14 to 19), a biphenyl-diyl group which may have a substituent (the following formulae 20 to 25), a terphenyl-diyl group which may have a substituent (the following formulae 26 to 28) and a condensed ring compound group which may have a substituent (the following formulae 29 to 38). The condensed ring compound group includes a fluorene-diyl group (the following formulae 36 to 38).

The divalent heterocyclic group represented by Ar¹ is one obtained by removing two hydrogen atoms from a heterocyclic compound such as furan, thiophene, pyrrole, pyrroline, pyrrolidine, oxazole, isooxazole, thiazole, isothiazole, imidazole, imidazoline, imidazolidine, pyrazole, pyrazoline, pyrazolidine, furazan, triazole, thiadiazole, oxadiazole, tetrazole, pyran, pyridine, piperidine, thiopyran, pyridazine, pyrimidine, pyrazine, piperazine, morpholine, triazine, benzofuran, isobenzofuran, benzothiophene, indole, isoindole, indolizine, indoline, isoindoline, chromene, chromane, isochromane, benzopyran, quinoline, isoquinoline, quinolizine, benzoimidazole, benzothiazole, indazole, naphthyridine, quinoxaline, quinazoline, quinazolidine, cinnoline, phthalazine, purine, pteridine, carbazole, xanthene, phenanthridine, acridine, β-carboline, perimidine, phenanthroline, thianthrene, phenoxathiin, phenoxazine, phenothiazine, phenazine and the like which may have a substituent. The substituent includes a halogen atom, an alkyl group which may have a substituent, an alkoxy group which may have a substituent, an alkylthio group which may have a substituent and an aryl group which may have a substituent. The definition and specific examples of the halogen atom, the alkyl group which may have a substituent, the alkoxy group which may have a substituent, the alkylthio group which may have a substituent and the aryl group which may have a substituent are the same as the definition and specific examples of the halogen atom, the alkyl group which may have a substituent, the alkoxy group which may have a substituent, the alkylthio group which may have a substituent and the aryl group which may have a substituent represented by R¹ and R². The divalent heterocyclic group is preferably a divalent aromatic heterocyclic group.

Specific examples of the divalent heterocyclic group includes the following groups.

A divalent heterocyclic group containing nitrogen as a hetero atom:

A pyridine-diyl group which may have a substituent (the following formulae 39 to 44).

A diazaphenylene group which may have a substituent (the following formulae 45 to 46).

A quinolinediyl group which may have a substituent (the following formulae 49 to 63).

A quinoxalinediyl group which may have a substituent (the following formulae 64 to 66).

An acridinediyl group which may have a substituent (the following formulae 69 to 72).

A bipyridyldiyl group which may have a substituent (the following formulae 73 to 75).

A phenanthrolinediyl group which may have a substituent (the following formulae 76 to 78).

A group containing silicon, nitrogen, sulfur, selenium and the like as a hetero atom and having a fluorine structure (the following formulae 79 to 93).

A 5-membered ring heterocyclic group containing silicon, nitrogen, sulfur, selenium and the like as a hetero atom (the following formulae 94 to 98).

A 5-membered ring condensed hetero group containing silicon, nitrogen, sulfur, selenium and the like as a hetero atom (the following formulae 99 to 110).

A 5-membered ring heterocyclic group containing silicon, nitrogen, sulfur, selenium and the like as a hetero atom:

Groups linking at α-position of the hetero atom to form a dimer or an oligomer (the following formulae 111 to 112).

A group linking to a phenyl group at α-position of the hetero atom (the following formulae 113 to 119).

A group obtained by condensing a benzene ring and a thiophene ring (the following formulae 120 to 122).

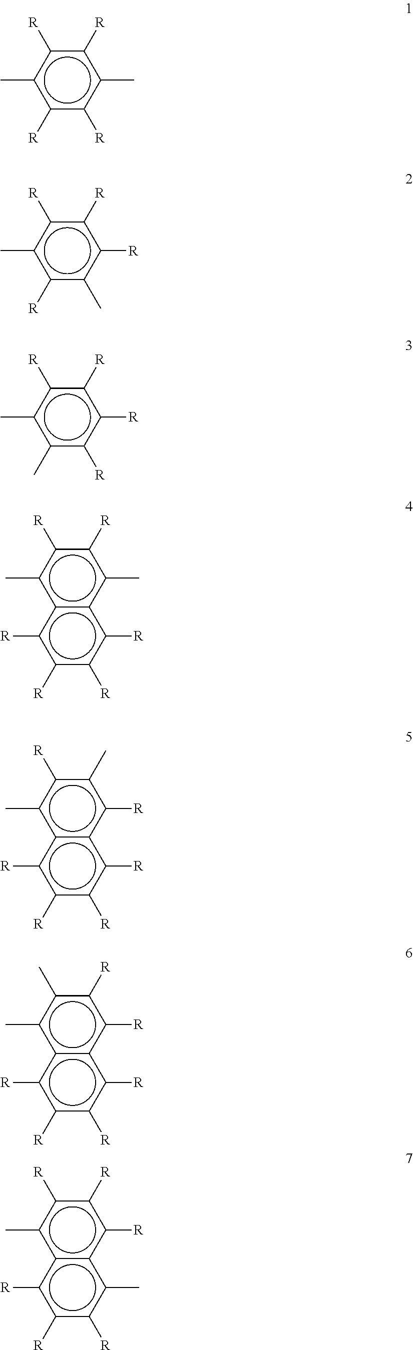

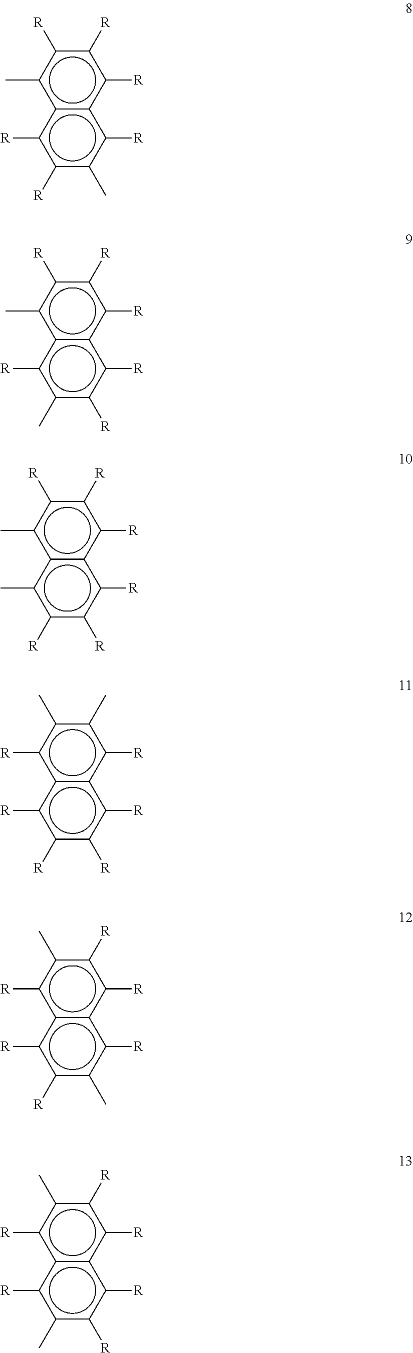

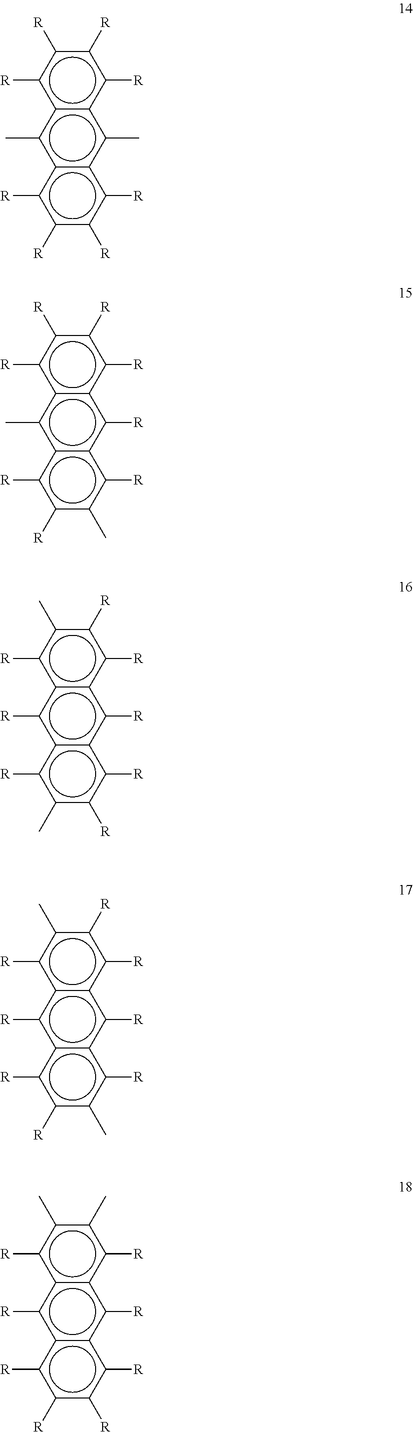

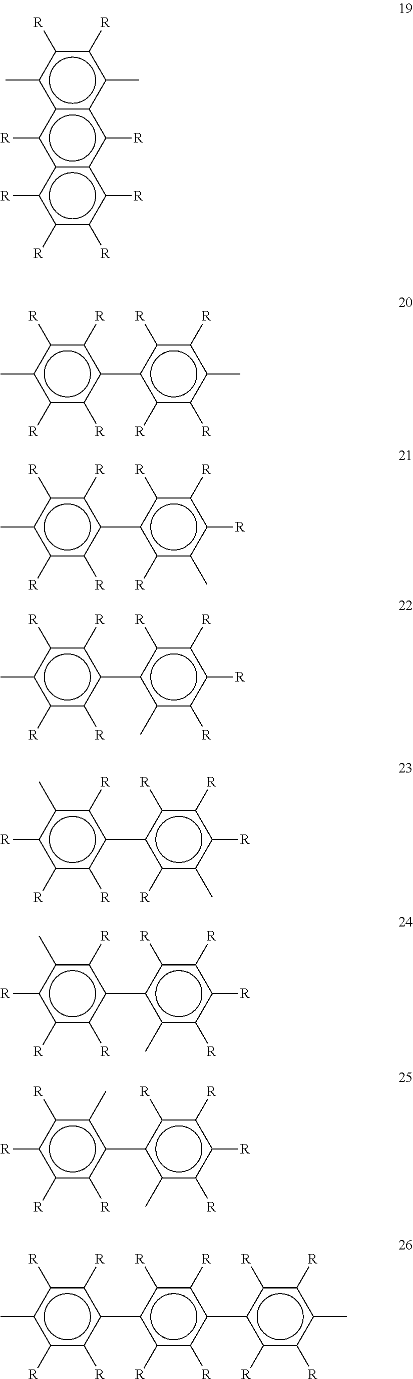

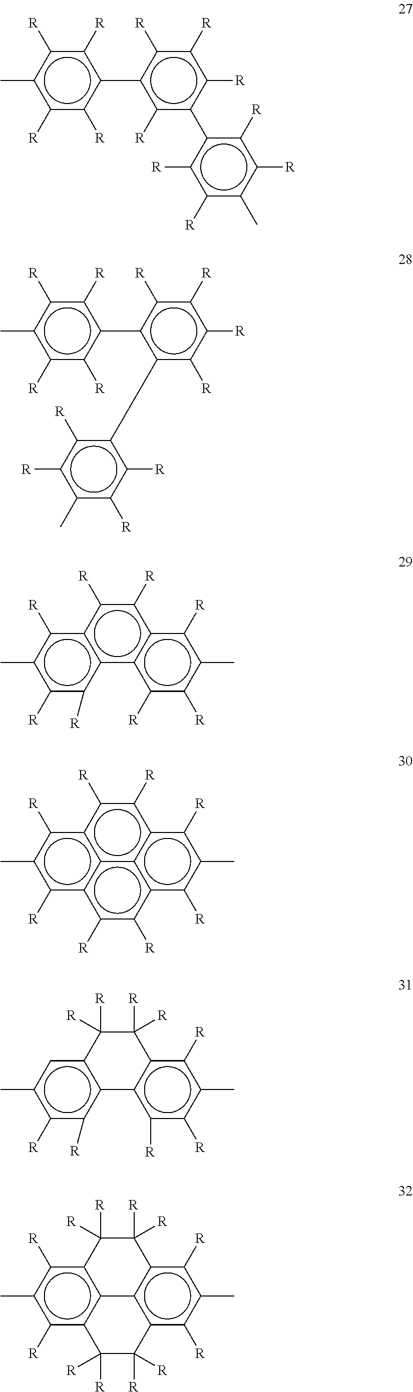

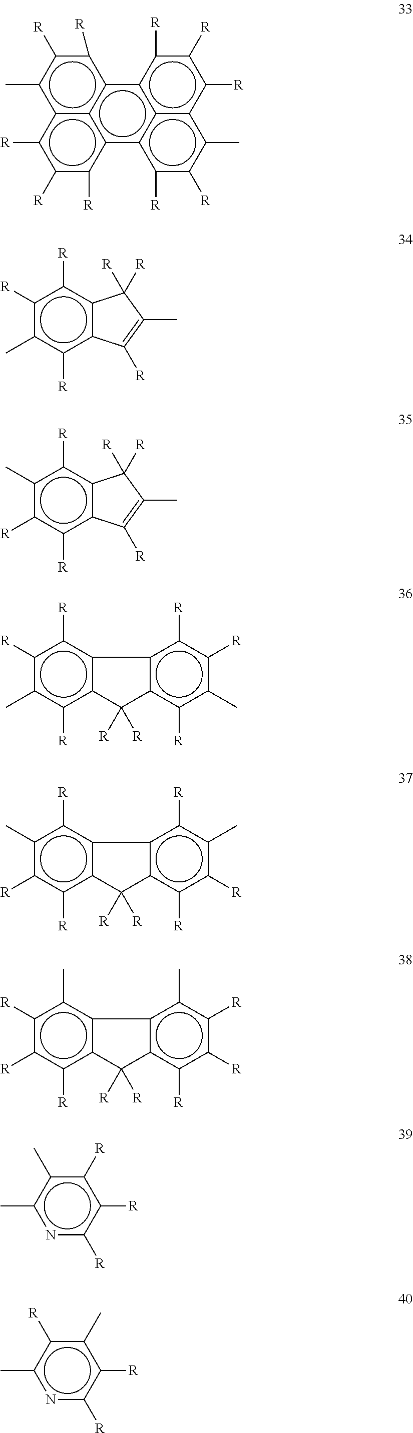

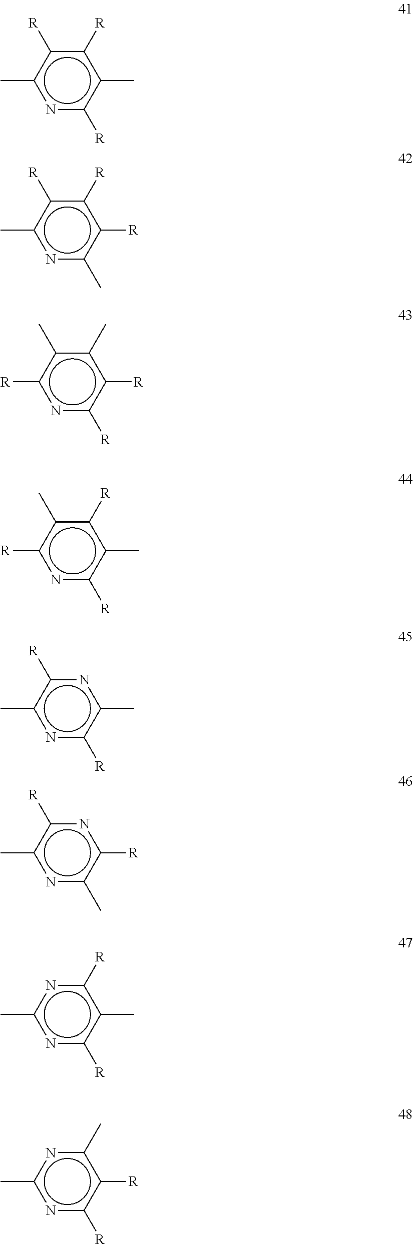

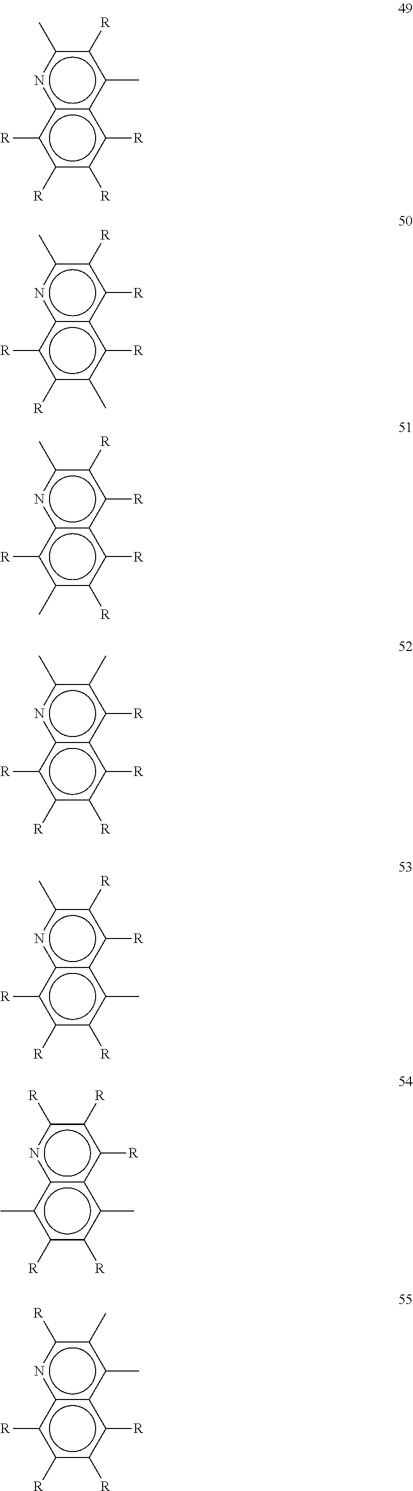

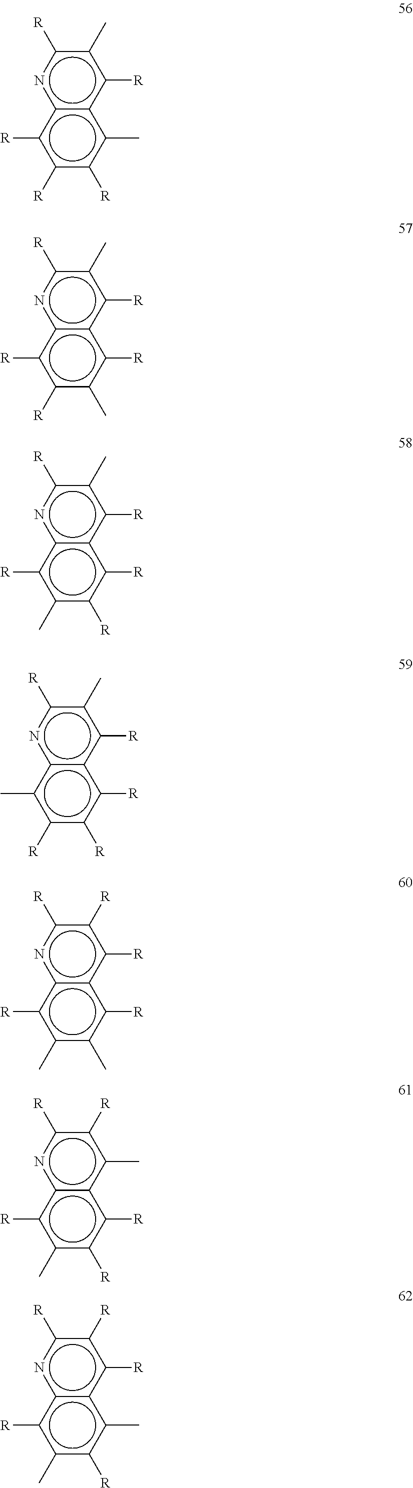

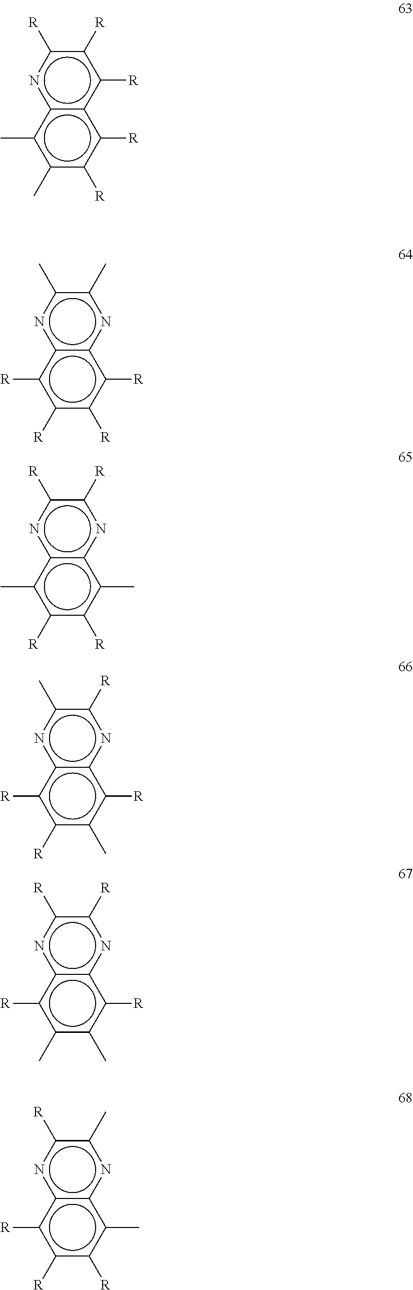

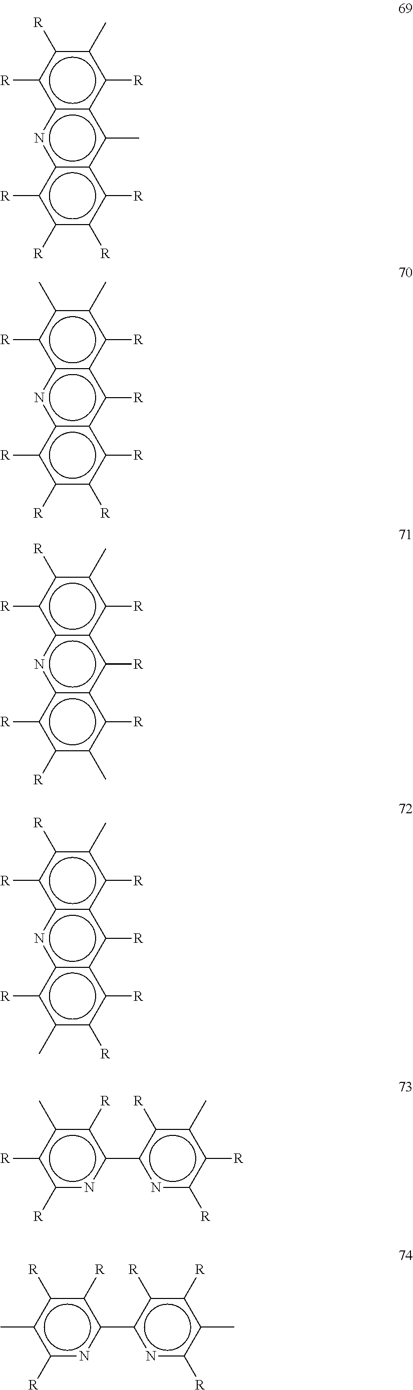

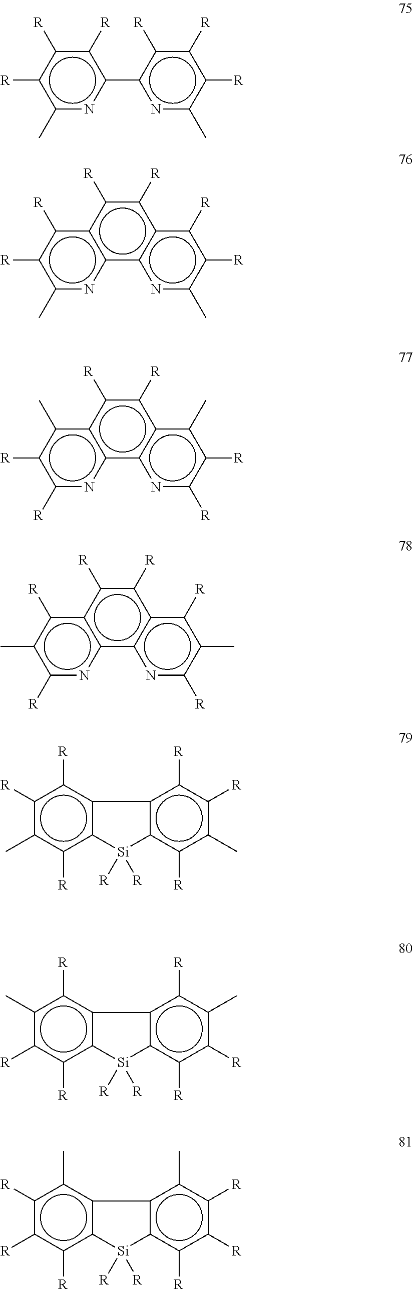

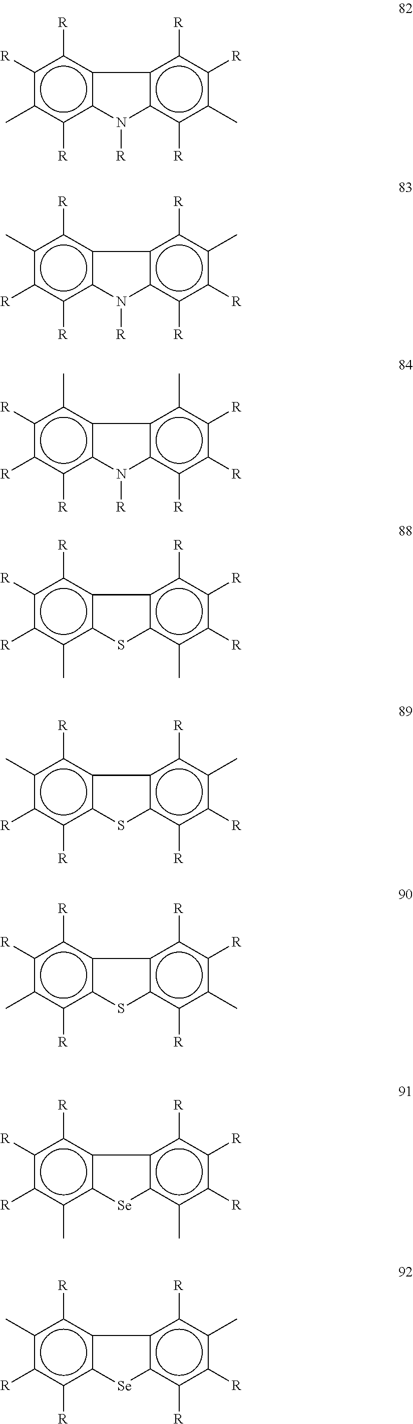

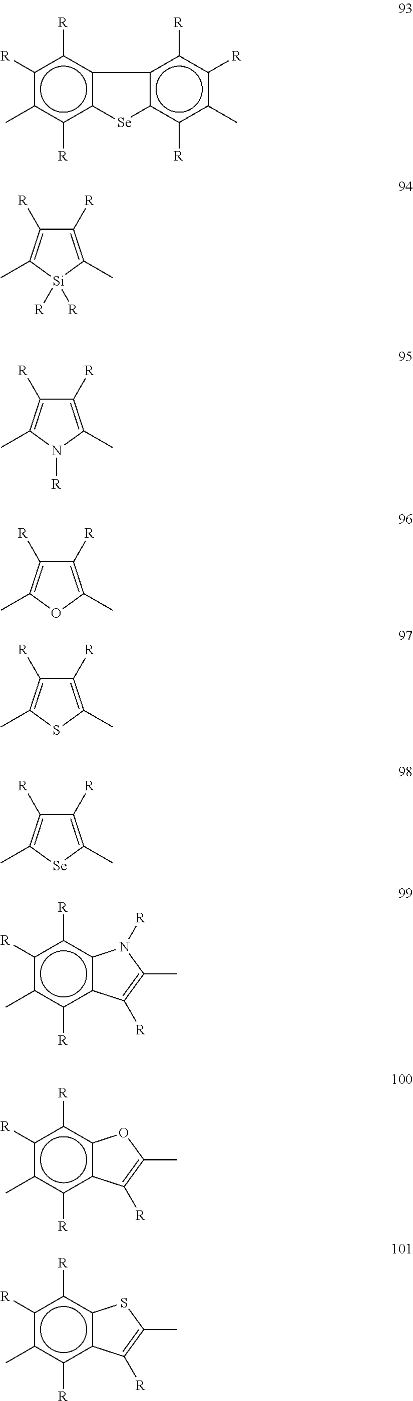

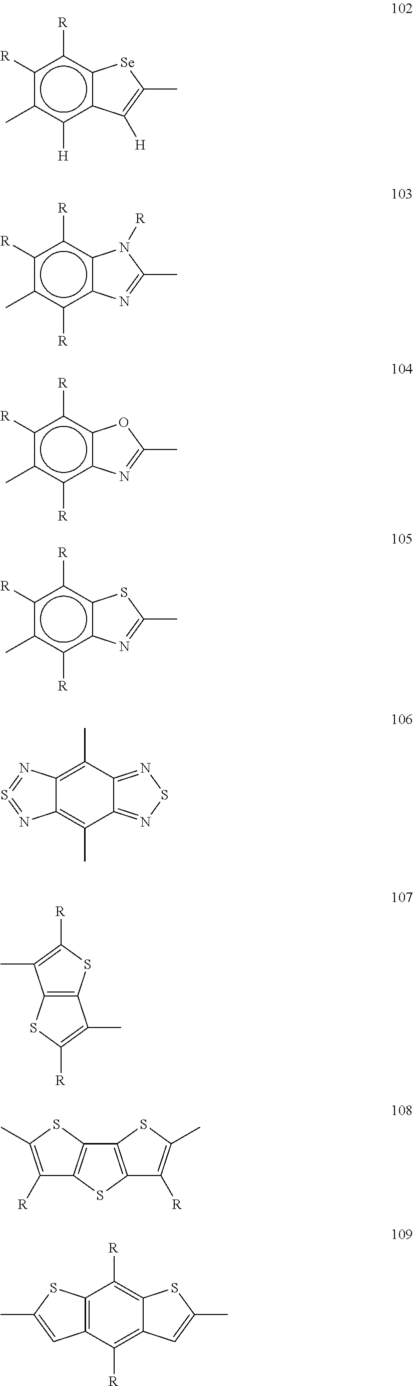

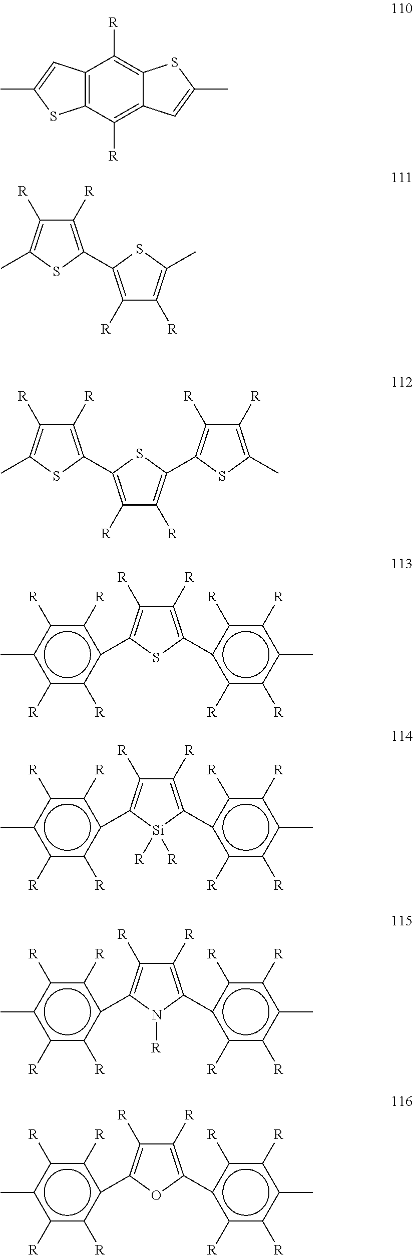

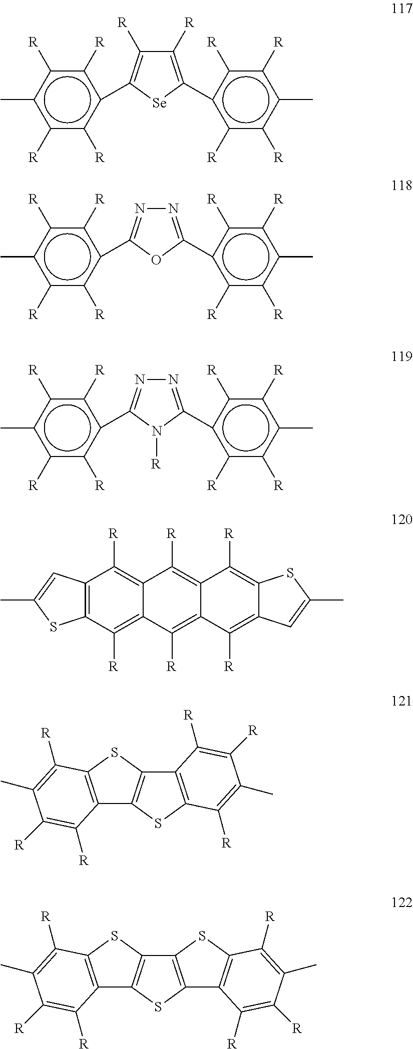

In the formulae 1 to 122, R represents the same meaning as described above.

The constitutional unit represented by the formula (3) includes preferably constitutional units represented by the formulae (3-1) to (3-8) from the standpoint of enhancement of short circuit current density of an organic photoelectric conversion device containing the composition of the present invention.

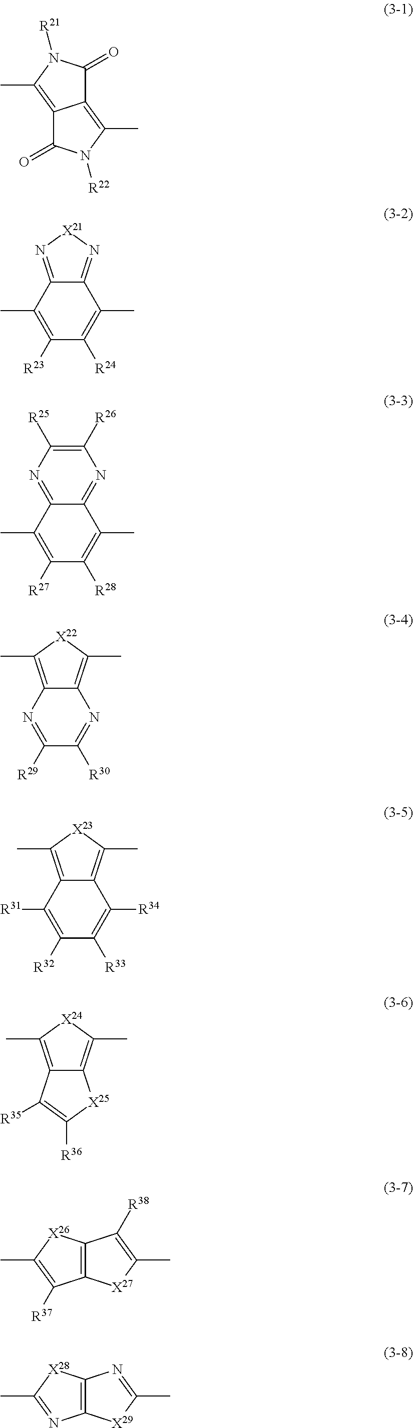

In the formulae (3-1) to (3-8), R²¹ to R³⁸ represent each independently a hydrogen atom or a substituent. The definition and specific examples of the substituent represented by R²¹ to R³⁸ are the same as the definition and specific examples of the substituent represented by R¹ and R².

R²¹, R²² and R³⁵ represent preferably an alkyl group which may have a substituent, an alkoxy group which may have a substituent or an alkylthio group which may have a substituent, more preferably an alkyl group which may have a substituent or an alkoxy group which may have a substituent, particularly preferably an alkyl group which may have a substituent. The alkyl group is preferably a branched alkyl group from the standpoint of enhancement of solubility of the first compound in an organic solvent.

R²³, R²⁴, R²⁷, R²⁸, R³¹, R³², R³³, R³⁴, R³⁷ and R³⁸ represent preferably a halogen atom or a hydrogen atom, more preferably a fluorine atom or a hydrogen atom.

R²⁵, R²⁶, R²⁹ and R³⁰ represent preferably a hydrogen atom, a halogen atom, an alkyl group which may have a substituent, an aryl group which may have a substituent or an arylalkyl group which may have a substituent, more preferably a hydrogen atom or an arylalkyl group which may have a substituent.

R³⁶ represents preferably a hydrogen atom, a halogen atom, an acyl group or an acyloxy group, more preferably an acyl group or an acyloxy group.

In the formulae (3-1) to (3-8), X²¹ to X²⁹ represent each independently a sulfur atom, an oxygen atom or a selenium atom. X²¹ to X²⁹ represent preferably a sulfur atom or an oxygen atom, more preferably a sulfur atom.

The constitutional unit represented by the formula (3) is more preferably a constitutional unit represented by the formulae (3-1) to (3-6), particularly preferably a constitutional unit represented by the formula (3-2). Specific examples of the constitutional unit represented by the formula (3-2) include constitutional units represented by the formulae (3-2-1) to (3-2-9).

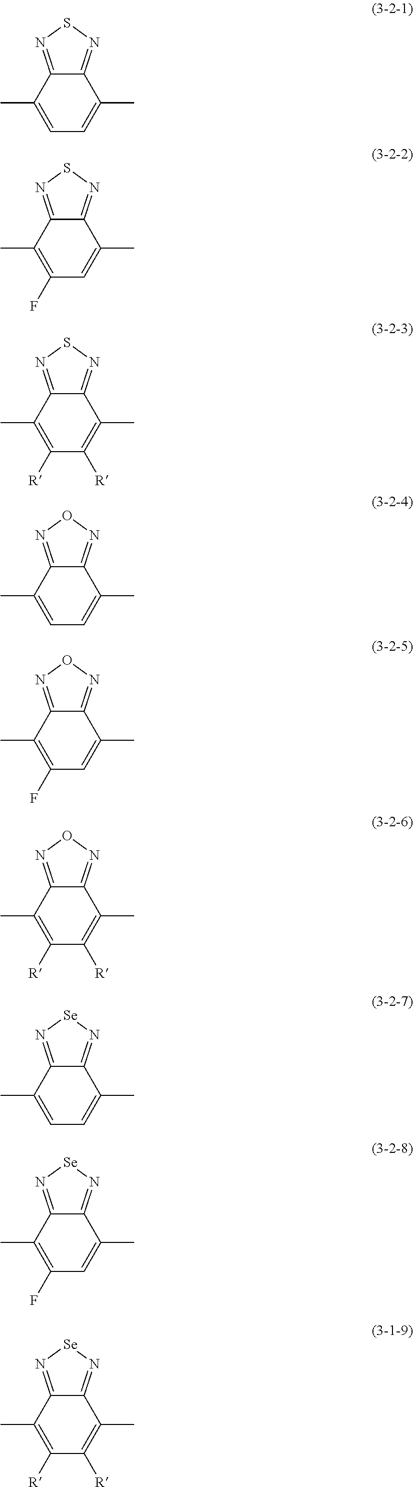

In the formulae (3-2-1) to (3-2-9), R′ represents a substituent. The definition and specific examples of the substituent represented by R′ are the same as the definition and specific examples of the substituent represented by R¹ and R².

The polymer compound in the present invention denotes a compound having a weight-average molecular weight of 1000 or more. The weight-average molecular weight of the polymer compound of the present invention is preferably 3000 to Ser. No. 10/000,000, more preferably 8000 to 5000000, particularly preferably 10000 to 1000000.

When the weight-average molecular weight of the polymer compound of the present invention is smaller than 3000, coatability lowers in some cases when used in fabrication of a device. When the weight-average molecular weight is larger than 10000000, solubility in a solvent and coatability lower in some cases when used in fabrication of a device.

The weight-average molecular weight of the polymer compound in the present invention denotes polystyrene-equivalent weight-average molecular weight measured by gel permeation chromatography (GPC).

It is desirable that the solubility of the first compound and the second compound in a solvent is high from the standpoint of easiness of fabrication of the device. Specifically, it is preferable that the polymer compound of the present invention has solubility by which a solution containing the polymer compound in an amount of 0.01 wt % or more can be produced, it is more preferable that is has solubility by which a solution containing the polymer compound in an amount of 0.1 wt % or more can be produced, it is further preferable that it has solubility by which a solution containing the polymer compound in an amount of 0.4 wt % or more can be produced.

Thought the method of producing a polymer compound composed of a constitutional unit represented by the formula (1) and a constitutional unit represented by the formula (3) and a polymer compound composed of a constitutional unit represented by the formula (2) and a constitutional unit represented by the formula (3) is not particularly restricted, preferable are methods using the Suzuki coupling reaction and the Stille coupling reaction from the standpoint of easiness of synthesis of the polymer compound.

The method of using the Suzuki coupling reaction includes, for example, a production method having a step of reacting at least one compound represented by the formula (100):

Q¹⁰⁰-E¹-Q²⁰⁰ (100)

(wherein E¹ represents a constitutional unit represented by the formula (3). Q¹⁰⁰ and Q²⁰⁰ represent each independently a dihydroxyboryl group [—B(OH)₂] or a borate residue.)
and at least one compound represented by the formula (200):

T¹-E²-T² (200)

(wherein E² represents a constitutional unit represented by the formula (1) or a constitutional unit represented by the formula (2). T¹ and T² represent each independently a halogen atom or a sulfonic acid residue.)
in the presence of a palladium catalyst and a base. E¹ is preferably a constitutional unit represented by the formulae (3-1) to (3-8).

In the case of use of the Suzuki coupling reaction, it is preferable that the total number of moles of two or more compounds represented by the formula (200) used in the reaction is excess over the total number of moles of at least one compound represented by the formula (100). When the total number of moles of at least one compound represented by the formula (200) used in the reaction is 1 mol, the total number of moles of at least one compound represented by the formula (100) is preferably 0.6 to 0.99 mol, further preferably 0.7 to 0.95 mol.

The borate residue means a group obtained by removing a hydroxyl group from a boric acid diester, and includes a dialkyl ester residue, a diaryl ester residue, a di(arylalkyl)ester residue and the like. As specific examples of the borate residue, groups represented by the following formulae are exemplified.

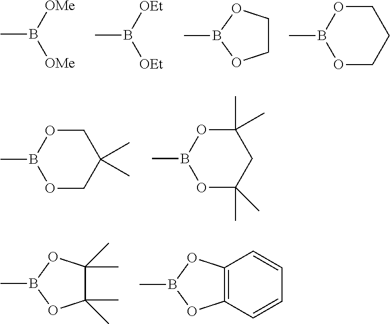

(wherein Me represents a methyl group and Et represents an ethyl group.).

The halogen atom represented by T¹ and T² in the formula (200) includes a fluorine atom, a chlorine atom, a bromine atom and an iodine atom. From the standpoint of easiness of synthesis of the polymer compound, a bromine atom and an iodine atom are preferable, a bromine atom is more preferable.

The sulfonic acid residue represented by T¹ and T² in the formula (200) denotes an atomic group obtained by removing an acidic hydrogen from sulfonic acid (—SC₃H), and specific examples thereof include alkyl sulfonate groups (for example, a methane sulfonate group, an ethane sulfonate group), aryl sulfonate groups (for example, a benzene sulfonate group, a p-toluene sulfonate group), arylalkyl sulfonate groups (for example, a benzyl sulfonate group) and a trifluoromethane sulfonate group.

The method of conducting the Suzuki coupling reaction includes, specifically, a method of reacting in the presence of a base using a palladium catalyst as the catalyst in any solvent.

The palladium catalyst used in the Suzuki coupling reaction includes, for example, Pd(0) catalyst and Pd(II) catalyst, specifically, palladium[tetrakis(triphenylphosohine)], palladium acetates, dichlorobis(triphenylphosphine)palladium, palladium acetate, tris(dibenzylideneacetone)dipalladium, bis(dibenzylideneacetone)palladium, and from the standpoint of easiness of the reaction (polymerization) operation and the reaction (polymerization) speed, preferable are dichlorobis(triphenylphosphine)palladium, palladium acetate and tris(dibenzylideneacetone)dipalladium.

The addition amount of the palladium catalyst is not particularly restricted, and amounts effective as the catalyst are permissible, and the amount with respect to 1 mol of a compound represented by the formula (100) is usually 0.0001 mol to 0.5 mol, preferably 0.0003 mol to 0.1 mol.

When palladium acetates are used as the palladium catalyst to be used in the Suzuki coupling reaction, phosphorus compounds such as triphenylphosphine, trio-tolyl)phosphine, trio-methoxyphenyl)phosphine and the like can be added as a ligand. In this case, the addition amount of a ligand is usually 0.5 mol to 100 mol, preferably 0.9 mol to 20 mol, further preferably 1 mol to 10 mol with respect to 1 mol of the palladium catalyst.

The base to be used in the Suzuki coupling reaction includes inorganic bases, organic bases and inorganic salts. The inorganic base includes, for example, potassium carbonate, sodium carbonate and barium hydroxide. The organic base includes, for example, triethylamine and tributylamine. The inorganic salt includes, for example, cesium fluoride.

The addition amount of the base is usually 0.5 mol to 100 mol, preferably 0.9 mol to 20 mol, further preferably 1 mol to 10 mol with respect to 1 mol of a compound represented by the formula (100).

The Suzuki coupling reaction is usually carried out in a solvent. As the solvent, exemplified are N,N-dimethylformamide, toluene, dimethoxyethane and tetrahydrofuran. From the standpoint of solubility of the polymer compound used in the present invention, toluene and tetrahydrofuran are preferable. It may be permissible that an aqueous solution of a base is added, and the reaction is performed in a two-phase system. When an inorganic salt is used as the base, it is usual that an aqueous solution of a base is added and the reaction is performed, from the standpoint of solubility of the inorganic salt.

When an aqueous solution of a base is added and the reaction is performed in a two-phase system, a phase transfer catalyst such as quaternary ammonium salts and the like may be added, if required.

The temperature for conducting the Suzuki coupling reaction is usually about 50 to 160° C., depending on the above-described solvent, and the temperature is preferably 60 to 120° C., from the standpoint of increasing the molecular weight of the polymer compound. It may also be permissible that the temperature is raised up close to the boiling point of a solvent and reflux is performed. Though the time when the intended degree of polymerization is attained is defined as the end point, the reaction time is usually 0.1 hour to 200 hours. The reaction times around 1 hour to 30 hours are efficient and preferable.

The Suzuki coupling reaction is conducted in a reaction system not deactivating a Pd(0) catalyst, under an inert atmosphere such as an argon gas, a nitrogen gas and the like. It is conducted, for example, in a system sufficiently deaerated with an argon gas, a nitrogen gas and the like. Specifically, an atmosphere in a polymerization vessel (reaction system) is deaerated by sufficiently purging with a nitrogen gas, then, a compound represented by the formula (100), a compound represented by the formula (200) and dichlorobis(triphenylphosphine)palladium(II) are charged into this polymerization vessel, further, an atmosphere in the polymerization vessel is deaerated by sufficiently purging with a nitrogen gas, then, a solvent deaerated by previously bubbling with a nitrogen gas, for example, toluene, is added, then, a base deaerated by previously bubbling with a nitrogen gas, for example, a sodium carbonate aqueous solution is dropped into this solution, then, the solution is heated and the temperature is raised, for example, up to the reflux temperature, and polymerization is carried out at this reflux temperature for 8 hours while keeping an inert atmosphere.

The method of using the Stille coupling reaction includes, for example, a production method having a step of reacting at least one compound represented by the formula (300):

Q³⁰⁰-E⁵-Q⁴⁰⁰ (300)

(wherein E³ represents a constitutional unit represented by the formula (3). Q³⁰⁰ and Q⁴⁰⁰ represent each independently a substituted stannyl group.). and at least one compound represented by the formula (200) described above in the presence of a palladium catalyst. E³ is preferably a constitutional unit represented by the formulae (3-1) to (3-8).

The substituted stannyl group includes a group represented by —SnR¹⁰⁰₃ and the like. Here, R¹⁰⁰ represents a monovalent organic group. The monovalent organic group includes an alkyl group, an aryl group and the like.

The number of carbon atoms of the alkyl group is usually 1 to 30, and specific examples thereof include linear alkyl groups such as a methyl group, an ethyl group, a propyl group, an isopropyl group, a butyl group, an isobutyl group, a sec-butyl group, a tert-butyl group, a pentyl group, an isopentyl group, a 2-methylbutyl group, a 1-methylbutyl group, a hexyl group, an isohexyl group, a 3-methylpentyl group, a 2-methylpentyl group, a 1-methylpentyl group, a heptyl group, an octyl group, an isooctyl group, a 2-ethylhexyl group, a nonyl group, a decyl group, an undecyl group, a dodecyl group, a tetradecyl group, a hexadecyl group, an octadecyl group, an eicosyl group and the like, and cycloalkyl groups such as a cyclopentyl group, a cyclohexyl group, an adamantyl group and the like. The aryl group includes a phenyl group, a naphthyl croup and the like. The substituted stannyl group includes preferably —SnMe₃, —SnEt₃, —SnBu₃ and —SnPh₃, further preferably —SnMe₃, —SnEt₃ and —SnBu₃. In the above-described preferable examples, Me represents a methyl group, Et represents an ethyl group, Bu represents a butyl group and Ph represents a phenyl group.

The halogen atom represented by T¹ and T² in the formula (200) includes a fluorine atom, a chlorine atom, a bromine atom and an iodine atom. From the standpoint of easiness of synthesis of the polymer compound, a bromine atom and an iodine atom are preferable.

As the alkyl sulfonate group represented by T¹ and T² in the formula (200), a methane sulfonate group, an ethane sulfonate group and a trifluoromethane sulfonate group are exemplified. As the aryl sulfonate group, a benzene sulfonate group and a p-toluene sulfonate group are exemplified. As the aryl sulfonate group, a benzyl sulfonate group is exemplified.

Specific examples thereof include a method of reacting in any solvent in the presence of, for example, a palladium catalyst as the catalyst.

The palladium catalyst used in the Stille coupling reaction includes, for example, Pd(0) catalysts and Pd(II) catalysts. Specifically, palladium[tetrakis(triphenylphosphine)], palladium acetates, dichlorobis(triphenylphosphine)palladium, palladium acetate, tris(dibenzylideneacetone)dipalladium and bis(dibenzylideneacetone)palladium are mentioned, and from the standpoint of easiness of the reaction (polymerization) operation and the reaction (polymerization) speed, preferable are palladium[tetrakis(triphenylphosphine)] and tris(dibenzylideneacetone)dipalladium.

The addition amount of the palladium catalyst used in the Stille coupling reaction is not particularly restricted, and amounts effective as the catalyst are permissible, and the amount with respect to 1 mol of a compound represented by the formula (300) is usually 0.0001 mol to 0.5 mol, preferably 0.0003 mol to 0.2 mol.

In the Stille coupling reaction, a ligand and a co-catalyst can also be used, if necessary. The ligand includes, for example, phosphorus compounds such as triphenylphosphine, tri(o-tolyl)phosphine, tri(o-methoxyphenyl)phosphine, tris(2-furyl)phosphine and the like, and arsenic compounds such as triphenylarsine, triphenoxyarsine and the like. The co-catalyst includes copper iodide, copper bromide, copper chloride, copper(I) 2-thenoate and the like.

In the case of use of a ligand or a co-catalyst, the addition amount of a ligand or a co-catalyst is usually 0.5 mol to 100 mol, preferably 0.9 mol to 20 mol, further preferably 1 mol to 10 mol with respect to 1 mol of a palladium catalyst.

The Stille coupling reaction is usually conducted in a solvent. The solvent includes N,N-dimethylformamide, N, N-dimethylacetamide, toluene, dimethoxyethane, tetrahydrofuran and the like. From the standpoint of solubility of the polymer compound used in the present invention, toluene and tetrahydrofuran are preferable.

The temperature for conducting the Stille coupling reaction is usually about 50 to 160° C., depending on the solvent described above, however, from the standpoint of increasing the molecular weight of the polymer compound, it is preferably 60 to 120° C. It may also be permissible that the temperature is raised up close to the boiling point of a solvent and reflux is performed.

Though the time when the intended degree of polymerization is attained is defined as the end point, the time for effecting the above-described reaction (reaction time) is usually about 0.1 hour to 200 hours. The reaction times around 1 hour to 30 hours are efficient and preferable.

The Stille coupling reaction is conducted in a reaction system not deactivating a Pd catalyst, under an inert atmosphere such as an argon gas, a nitrogen gas and the like. It is conducted, for example, in a system sufficiently deaerated with an argon gas, a nitrogen gas and the like. Specifically, an atmosphere in a polymerization vessel (reaction system) is deaerated by sufficiently purging with a nitrogen gas, then, a compound represented by the formula (300), a compound represented by the formula (200) and a palladium catalyst are charged into this polymerization vessel, further, an atmosphere in the polymerization vessel is deaerated by sufficiently purging with a nitrogen gas, then, a solvent deaerated by previously bubbling with a nitrogen gas, for example, toluene, is added, then, if necessary, a ligand and a co-catalyst are added, and thereafter, the solution is heated and the temperature is raised, for example, up to the reflux temperature, and polymerization is carried out at this reflux temperature for 8 hours while keeping an inert atmosphere.

The polystyrene-equivalent number-average molecular weight of the first compound and the second compound is preferably 1×10³ to 1×10⁸. When the polystyrene-equivalent number-average molecular weight is 1×10³ or more, a tough film is obtained easily. While, when the polystyrene-equivalent number-average molecular weight is 1×10⁸ or lower, solubility of the compound is high and fabrication of a film is easy.

The polystyrene-equivalent number-average molecular weight of the first compound and the second compound is preferably 3000 or more.

If a polymerization active group remains intact at the end of the first compound and the second compound, there is a possibility of lowering of the life and the property of a device obtained when the compound is used for fabrication of the device (for example, photoelectric conversion device), therefore, it may be protected with a stable group. Those having a conjugated bond consecutive to the conjugated structure of the main chain are preferable as the end group. For example, structures having a linkage to an aryl group or a heterocyclic group via a vinylene group may also be used.

A monomer as a raw material of the first compound and the second compound in which Y¹ and Y² represent an oxygen atom can be synthesized, for example, according to a description of WO2011/052709.

A compound represented by the formula (A-1) in which Y¹ is —C(═O)— among monomers as a raw material of the first compound can be obtained, for example, by bromination of a compound represented by the formula (B-1).

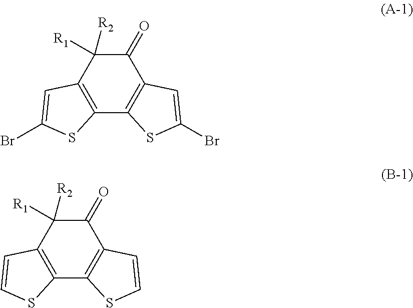

(in the formulae (A-1) and (B−1), R¹ and R² represent the same meaning as described above.)

A compound represented by the formula (A-2) in which Y² is —C(═O)— among monomers as a raw material of the second compound can be obtained, for example, by bromination of a compound represented by the formula (B-2).

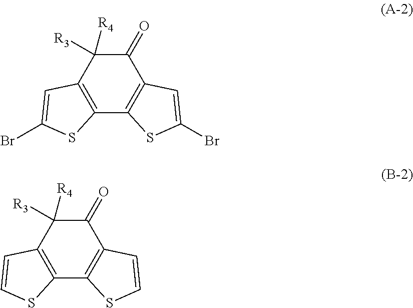

(in the formulae (A-2) and (B-2), R³ and R⁴ represent the same meaning as described above, provided that R³ and R⁴ are different from R¹ and R².)

For bromination, known methods can be used. The method of bromination includes, for example, a method of bromination using a brominating agent in a solvent or without solvent.

The solvent includes saturated hydrocarbons such as pentane, hexane, heptane, octane, cyclohexane and the like, unsaturated hydrocarbons such as benzene, toluene, ethylbenzene, xylene and the like, halogenated saturated hydrocarbons such as carbon tetrachloride, chloroform, dichloromethane, chlorobutane, bromobutane, chloropentane, bromopentane, chlorohexane, bromohexane, chlorocyclohexane, bromocyclohexane and the like, halogenated unsaturated hydrocarbons such as chlorobenzene, dichlorobenzene, trichlorobenzene and the like, etc.

The brominating agent includes bromine, N-bromosuccinimide (hereinafter, referred to as NBS in some cases), carbon tetrachloride, hydrobromic acid and the like. It is also possible to use some of these brominating agents in combination. The use amount of the brominating agent is usually 2 to 100000 equivalent with respect to the number of moles of the compound represented by the formula (B-1) or (B-2).

It is also possible that a catalyst for promoting bromination is allowed to coexist in bromination. The catalyst includes metals such as iron, cobalt, nickel, copper and the like, halogenated metals such as iron halide, cobalt halide, nickel halide, copper halide and the like, radical generators such as benzoyl peroxide, azoisobutyronitrile and the like, etc. As the catalyst, metals and halogenated metals are preferable, iron and iron bromide are further preferable. The use amount of the catalyst is usually 0.001 to 10 equivalent, preferably 0.01 to 1 equivalent with respect to the number of moles of the compound represented by the formula (B-1) or (B-2). The reaction temperature is usually −50 to 200° C., preferably 0 to 150° C.

The compound represented by the formula (A-1) or (A-2) can be obtained by conducting usual post treatments such as extraction of the product with an organic solvent and distillation off of the solvent and the like after the reaction (for example, after stopping the reaction by addition of water). The product can be isolated and purified by methods such as chromatographic fractionation, recrystallization and the like.

The compound represented by the (B-1) can be obtained by reacting the compound represented by the formula (C-1) and an acid. The compound represented by the formula (B-2) can be obtained by reacting the compound represented by the formula (C-2) and an acid.

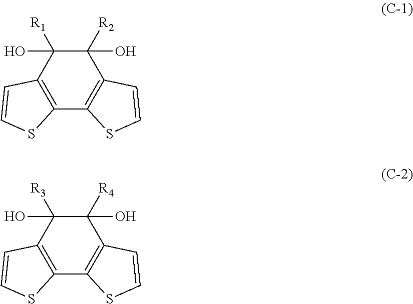

(in the formulae (C-1) to (C-2), R¹, R², R³ and R⁴ represent the same meaning as described above, provided that R³ and R⁴ are different from R¹ and R².)

As the acid, any of Lewis acids and Broensted acids may be used. Specific examples of the acid include hydrochloric acid, bromic acid, hydrofluoric acid, sulfuric acid, nitric acid, formic acid, acetic acid, propionic acid, oxalic acid, benzoic acid, boron trifluoride diethyl ether complex, aluminum chloride, tin(IV) chloride, silicon(IV) chloride, iron(III) chloride, titanium tetrachloride, zinc chloride, benzenesulfonic acid, p-toluenesulfonic acid, trifluoroacetic acid, tri fluoromethanesulfonic acid and a mixture thereof, and the like.

The reaction of the compound represented by the formula (C-1) or (C-2) and an acid may be carried out in the presence of only an acid or carried out in the presence of an acid and a solvent. Though the reaction temperature is not particularly restricted, temperatures in the range from −80° C. to the boiling point of a solvent are preferable.

The solvent includes saturated hydrocarbons such as pentane, hexane, heptane, octane, cyclohexane and the like, unsaturated hydrocarbons such as benzene, toluene, ethylbenzene, xylene and the like, halogenated saturated hydrocarbons such as carbon tetrachloride, chloroform, dichloromethane, chlorobutane, bromobutane, chloropentane, bromopentane, chlorohexane, bromohexane, chlorocyclohexane, bromocyclohexane and the like, halogenated unsaturated hydrocarbons such as chlorobenzene, dichlorobenzene, trichlorobenzene and the like, alcohols such as methanol, ethanol, propanol, isopropanol, butanol, tert-butyl alcohol and the like, carboxylic acids such as formic acid, acetic acid, propionic acid and the like, ethers such as dimethyl ether, diethyl ether, methyl tert-butyl ether, tetrahydropyran, tetrahydropyran, dioxane and the like, inorganic acids such as hydrochloric acid, bromic acid, hydrofluoric acid, sulfuric acid, nitric acid and the like, etc. The solvents may be used singly or in combination.

The compound represented by the formula (B-1) or (B-2) can be obtained by conducting usual post treatments such as extraction of the product with an organic solvent and distillation off of the solvent and the like after the reaction (for example, after stopping the reaction by addition of water). If necessary, the product may be further purified by chromatographic fractionation, recrystallization and the like.

The compound represented by the formula (C-1) or (C-2) can be obtained by reacting an alkyllitbium reagent or Grignard reagent and a compound 1.

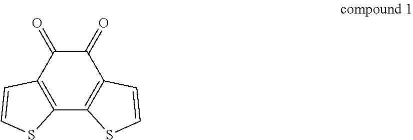 [SMILES: O=C1C(=O)c2ccsc2-c2sccc21]

The alkyllithium reagent includes methyllithium, ethyllithium, propyllithium, butyllithium, hexyllithium, 2-ethylhexyllithium, 3,7-dimethyloctyllithium, 3,7,11-trimethyldodecyllithium, 3-heptyldecyllithium, dodecyllithium, pentadecyllithium, hexadecyllithium, phenyllithium, naphthyllithium, benzyllithium, tolyllithium and the like.

The Grignard reagent includes methylmagnesium chloride, methylmagnesium bromide, ethylmagnesium chloride, ethylmagnesium bromide, propylmagnesium chloride, propylmagnesium bromide, butylmagnesium chloride, butylmagnesium bromide, hexylmagnesium chloride, hexylmagnesium bromide, 2-ethylhexylmagnesium chloride, 2-ethylhexylmagnesium bromide, 3,7-dimethyloctyl chloride, 3,7-dimethyloctyl bromide, 3,7,11-trimethyldodecyl bromide, 3-heptyldecyl bromide, octylmagnesium bromide, decylmagnesium bromide, dodecyl bromide, pentadecyl bromide, hexadecyl bromide, allylmagnesium chloride, allylmagnesium bromide, benzylmagnesium chloride, phenylmagnesium bromide, naphthylmagnesium bromide, tolylmagnesium bromide and the like.

The reaction of an alkyllithium reagent or Grignard reagent and a compound 1 may be carried out under an atmosphere of an inert gas such as a nitrogen gas, an argon gas and the like or may be carried out in the presence of a solvent. Though the reaction temperature is not particularly restricted, temperatures in the range from −80° C. to the boiling point of a solvent are preferable.

The solvent used in the reaction of an alkyllithium reagent or Grignard reagent and a compound 1 includes saturated hydrocarbons such as pentane, hexane, heptane, octane, cyclohexane and the like, unsaturated hydrocarbons such as benzene, toluene, ethylbenzene, xylene and the like, ethers such as dimethyl ether, diethyl ether, methyl tert-butyl ether, tetrahydrofuran, tetrahydropyran, dioxane and the like, etc. The solvents may be used singly or in combination.

A mixture containing the compound represented by the formula (C-1) or (C-2) can be obtained by conducting usual post treatments such as extraction of the product with an organic solvent and distillation off of the solvent and the like after the reaction (for example, after stopping the reaction by addition of water). If necessary, the product may be further purified by chromatographic fractionation, recrystallization and the like.

The composition of the present invention contains a third compound. The third compound includes an electron accepting compound and an electron donating compound, and an electron accepting compound is preferable. Whether the third compound is an electron accepting compound or an electron donating compound is determined relatively based on the energy level of the compound contained in the composition of the present invention.

Specific examples of the electron accepting compound include fullerene and derivatives thereof, carbon materials, metal oxides such as titanium oxide and the like, oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, perylene derivatives, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, and phenanthroline derivatives such as 2,9-dimethyl-4,7-diphenyl-1,10-phenanthroline (basocuproin) and the like. As the electron accepting compound, titanium oxide, carbon nanotubes, fullerene and derivatives thereof are preferable, fullerene and derivatives thereof are particularly preferable.

The fullerene and derivatives thereof include C_{6 0}, C7 0, C_{7 6}, C_{7 8}, C_{8 4} and derivatives thereof. The fullerene derivative means a compound obtained by at least partially modifying fullerene.

The fullerene derivative includes, for example, a compound represented by the formula (6), a compound represented the formula (7), a compound represented the formula (8) and a compound represented the formula (9)

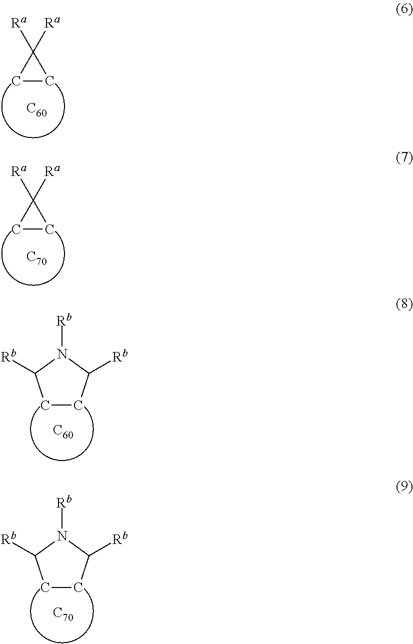

(in the formulae (6) to (9), R^{a} represents an alkyl group which may have a substituent, an aryl group which may have a substituent, a heterocyclic group or a group having an ester structure. A plurality of R^{a} may be the same or mutually different. R^{b} represents an alkyl group which may have a substituent or an aryl group which may have a substituent. A plurality of R^{b} may be the same or mutually different.)

The definition and specific examples of the alkyl group which may have a substituent, the aryl group which may have a substituent and the heterocyclic group represented by R^{a} and R^{b} are the same as the definition and specific examples of the alkyl group which may have a substituent, the aryl group which may have a substituent and the heterocyclic group represented by R¹ and R².

The group having an ester structure represented by R^{a} includes, for example, a group represented by the formula (10).

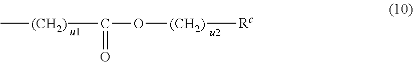

(wherein u1 represents an integer of 1 to 6, u2 represents an integer of 0 to 6, and R^{c} represents an alkyl group which may have a substituent, an aryl group which may have a substituent or a heterocyclic group.)

The definition and specific examples of the alkyl group which may have a substituent, the aryl group which may have a substituent and the heterocyclic group represented by R^{c} are the same as the definition and specific examples of the alkyl group which may have a substituent, the aryl group which may have a substituent and the heterocyclic group represented by R¹ and R².

The C_{6 0} fullerene derivative includes, for example, the following compounds.

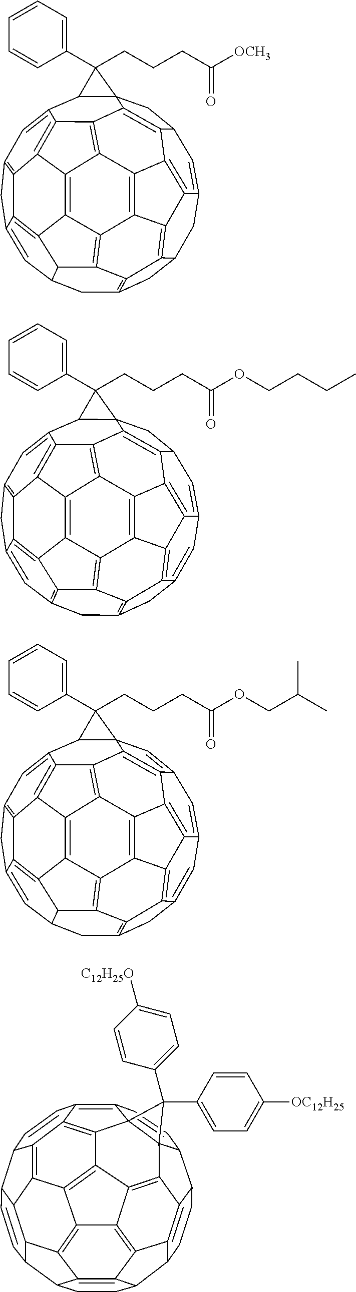

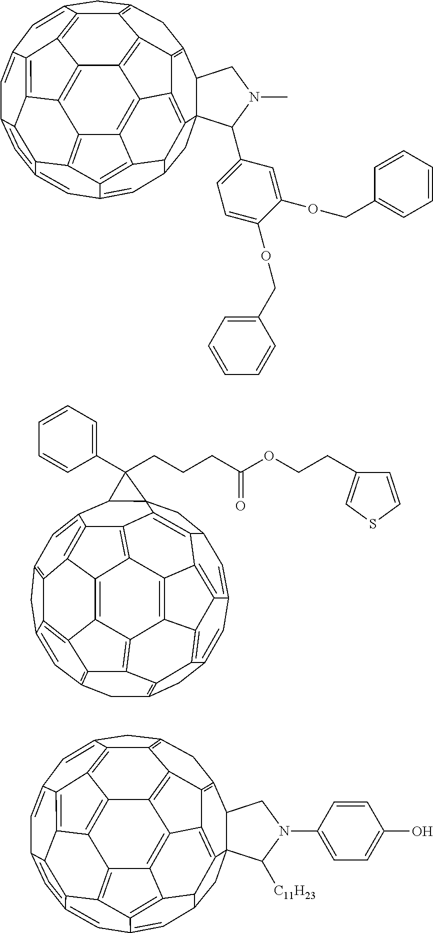

The C_{7 0} fullerene derivative includes, for example, the following compounds.

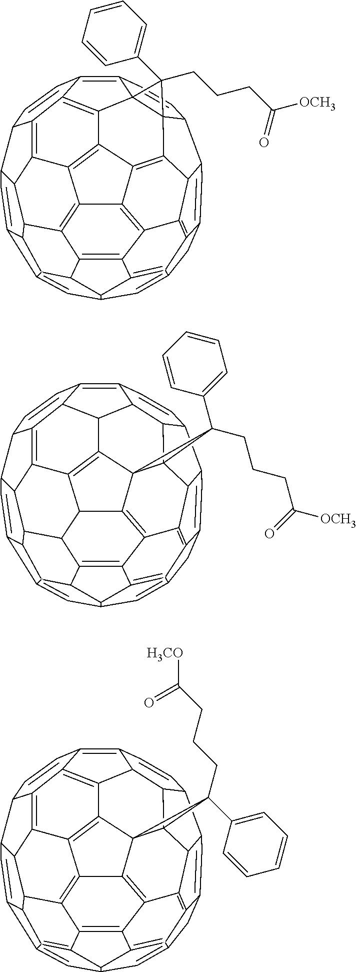 [SMILES: COC(=O)CCCC1(c2ccccc2)C23C4=C5C=CC6c7c5c2c2c5c7C7C6C=C6C8=CC9C=C%10CC%11=CC%12C%13C(=C2c2c-5c5c%14c%15c(c%10c%11c%13c2%15)C9C%14C8C6C57)C13C%12C=C4 ; COC(=O)CCCC1(c2ccccc2)C23C4=C5C6=C7C8C=CC9=C%10C=CC%11C%12C=C%13CC%14=CC%15C=C%16C%17=CC8C6C6C8C%18=c%19c(c%14c%13c(c%19=C2C58)C%12C31C%11C%10C4C97)C%15C%18C%16C%176 ; COC(=O)CCCC1(c2ccccc2)C23c4c5c6c7c8c4C4C9=C8C=CC7C7C=C8C%10=CC%11C=C%12CC%13=CC%14C(C=C9)C4C12C%14c1c%13c%12c2c4c9c(c-5c3c14)C(C8C%10=C9C2%11)C67]

Specific examples of the fullerene derivative include [6,6]phenyl-C61 butyric acid methyl ester (C60PCBM, [6,6]-Phenyl C61 butyric acid methyl ester), [6,6]phenyl-C71 butyric acid methyl ester (C70PCBM, [6,6]-Phenyl C71 butyric acid methyl ester), [6,6]phenyl-C85 butyric acid methyl ester (C84PCBM, [6,6]-Phenyl C85 butyric acid methyl ester) and [6,6]thienyl-C61 butyric acid methyl ester ([6,6]-Thienyl C61 butyric acid methyl ester).

The composition of the present invention may contain other compounds than the first compound, the second compound and the third compound. The compound includes, for example, pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having an aromatic amine residue in the side chain or main chain, polyaniline and derivatives thereof, polythiophene and derivatives thereof, polypyrrole and derivatives thereof, polyphenylenevinylene and derivatives thereof, and polythienylenevinylene and derivatives thereof.

The amount of the first compound contained in the composition of the present invention is preferably 4 to 40% by weight, further preferably 10 to 20% by weight. The amount of the second compound contained in the composition of the present invention is preferably 4 to 40% by weight, further preferably 10 to 20% by weight. The amount of the third compound contained in the composition of the present invention is preferably 50 to 80% by weight, further preferably 60 to 75% by weight.

The ratio of the weight of the third compound to the sum of the weight of the first compound and the weight of the second compound in the composition of the present invention is preferably 1.0 to 4.0, more preferably 2.0 to 3.0.

The ratio of the weight of the second compound to the weight of the first compound in the composition of the present invention is preferably 0.25 to 4.0, more preferably 0.67 to 1.5.

When the first compound is composed of a constitutional unit represented by the formula (1) and a constitutional unit represented by the formula (3), the number of the constitutional unit represented by the formula (1) contained in the first compound is preferably 30 to 70% with respect to the sum of the number of the constitutional unit represented by the formula (1) and number of the constitutional unit represented by the formula (3). When the second compound is composed of a constitutional unit represented by the formula (2) and a constitutional unit represented by the formula (3), the number of the constitutional unit represented by the formula (2) contained in the second compound is preferably 30 to 70% with respect to the sum of the number of the constitutional unit represented by the formula (2) and number of the constitutional unit represented by the formula (3).

The light absorption end wavelength of the first compound and the light absorption end wavelength of the second compound are both preferably 700 nm or more, more preferably 800 nm or more, further preferably 900 nm or more from the standpoint of improvement of the photoelectric conversion efficiency of an organic photoelectric conversion device containing the composition of the present invention.

The light absorption end wavelength in the present invention denotes a value measured by the following method.

For measurement of the absorption spectrum of a film containing the first compound and the second compound, use is made of a spectrophotometer functioning in a region of the wavelength of ultraviolet, visible and near-infrared (for example, ultraviolet visible near-infrared spectrophotometer JASCO-V670, manufactured by JASCO Corporation). When JASCO-V670 is used, measurement can be performed in a wavelength range of 300 to 2000 nm.

First, on a substrate (for example, quartz substrate, glass substrate), a film containing the first compound and the second compound is formed from a solution containing the first compound or the second compound or a melt containing the first compound or the second compound. Then, the absorption spectrum of the substrate and the absorption spectrum of a laminate of the film and the substrate are measured. The absorption spectrum of the film is obtained by subtracting the absorption spectrum of the substrate from the absorption spectrum of the laminate.

In the absorption spectrum of the film, the ordinate axis represents the absorbance of the first compound and the second compound and the abscissa axis represents wavelength. It is desirable to regulate the thickness of the film so that the maximum absorbance is about 0.3 to 2.

In the absorption spectrum of the film, a point situated at the longer wavelength side than the absorption peak at the longest wavelength side and showing 50% of the absorbance of the absorption peak is defined as P1, a point showing 25% thereof is defined as P2 and a point showing 10% thereof is defined as P3. Further, a point situated at the longer wavelength side by 100 nm than P3 is defined as P4 and a point situated at the longer wavelength side by 150 nm than P3 is defined as P5.

The light absorption end wavelength denotes the wavelength at an intersection point of the baseline and a straight line connecting P1 and P2. The baseline denotes a straight line connecting P4 and P5.

Since the composition of the present invention can manifest high electron and/or hole transportability, an device having the composition can transport electrons and holes injected from an electrode or charges generated by light absorption. By utilizing such properties, the composition of the present invention can be suitably used in various electronic devices such as an organic photoelectric conversion device, an organic film transistor, an organic electroluminescent device and the like. These devices will be illustrated individually below.

### <Organic Photoelectric Conversion Device>

An organic photoelectric conversion device having the composition of the present invention has at least one active layer containing the composition of the present invention between a pair of electrodes.

A preferable embodiment of the organic photoelectric conversion device having the composition of the present invention has a pair of electrodes at least one of which is transparent or semi-transparent, and an active layer containing the composition of the present invention.

The organic photoelectric conversion device having the composition of the present invention is usually formed on a substrate. This substrate may advantageously be one which does not chemically change in forming an electrode and in forming a layer of an organic material thereon. The material of the substrate includes, for example, glass, plastic, polymer film and silicon. In the case of an opaque substrate, it is preferable that the opposite electrode (namely, an electrode which is more remote from the substrate) is transparent or semitransparent.

Another embodiment of the organic photoelectric conversion device having the composition of the present invention is a photoelectric conversion device having a first active layer containing the composition of the present invention and a second active layer adjacent to the first active layer, between a pair of electrodes at least one of which is transparent or semitransparent.

The transparent or semitransparent electrode includes electrically conductive metal oxide films, semitransparent metal films and the like. Specifically, use is made of films fabricated using an electrically conductive material composed of indium oxide, zinc oxide, tin oxide, and a composite thereof: indium•tin•oxide (ITO), indium•zinc•oxide and the like; films of NESA, gold, platinum, silver, copper and the like, and preferable are films of ITO, indium•zinc•oxide and tin oxide. The electrode fabrication method includes a vacuum vapor deposition method, a sputtering method, an ion plating method, a plating method and the like.

As the electrode material, transparent electrically conductive films of organic materials such as polyaniline and derivatives thereof, polythiophene and derivatives thereof and the like may be used.

One electrode may not be transparent, and as the material of this electrode, metals, electrically conductive polymers and the like can be used. Specific examples of the electrode material include metals such as lithium, sodium, potassium, rubidium, cesium, magnesium, calcium, strontium, barium, aluminum, scandium, vanadium, zinc, yttrium, indium, cerium, samarium, europium, terbium, ytterbium and the like, and alloys composed of two or more of them and alloys composed of at least one of the above-described metals and at least one metal selected from the group consisting of gold, silver, platinum, copper, manganese, titanium, cobalt, nickel, tungsten and tin; graphite, graphite intercalation compounds, polyaniline and derivatives thereof, polythiophene and derivatives thereof. The alloy includes, for example, a magnesium-silver alloy, a magnesium-indium alloy, a magnesium-aluminum alloy, an indium-silver alloy, a lithium-aluminum alloy, a lithium-magnesium alloy, a lithium-indium alloy and a calcium-aluminum alloy.

As the means for improving photoelectric conversion efficiency, an additional intermediate layer other than the active layer may be used. The material used in the intermediate layer includes, for example, halides of alkali metals such as lithium fluoride and the like, halides of alkaline earth metals, oxides such as titanium oxide and the like; PEDOT (poly-3,4-ethylenedioxythiophene) and the like.

### <Active Layer>

The active layer is preferably a film composed of the composition of the present invention.

The thickness of the active layer is usually 1 nm to 100 μm. The thickness of the active layer is preferably 2 nm to 1000 nm, more preferably 5 nm to 500 nm, further preferably 20 nm to 200 nm.

The above-described active layer may be produced by any methods. For example, a method of coating a solution containing the composition of the present invention, and the like are mentioned.

### <Method of Producing Organic Photoelectric Conversion Device>

A preferable method of producing an organic photoelectric conversion device is a production method of a device having a first electrode and a second electrode and an active layer between the first electrode and the second electrode, comprising a step of coating a solution (ink) containing the composition of the present invention and a solvent to form the active layer on the first electrode and a step of forming the second electrode on the active layer.

The solvent for dissolving the composition of the present invention includes, for example, hydrocarbon solvents such as toluene, xylene, mesitylene, tetralin, devalin, bicyclohexyl, butylbenzene, sec-butylbenzene, tert-butylbenzene and the like, halogenated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane, chlorobenzene, dichlorobenzene, trichlorobenzene and the like, and ether solvents such as tetrahydrofuran, tetrahydropyran and the like. The composition of the present invention can be dissolved usually in an amount of 0.1% by weight or more in the above-described solvent.

As the method of coating a solution (ink) containing the composition of the present invention and a solvent, methods such as a slit coat method, a knife coat method, a spin coat method, a casting method, a micro gravure coat method, a gravure coat method, a bar coat method, a roll coat method, a wire bar coat method, a dip coat method, a spray coat method, a screen printing method, a gravure printing method, a flexo printing method, an offset printing method, an inkjet coat method, a dispenser printing method, a nozzle coat method, a capillary coat method and the like can be used. As the method of coating a solution (ink) containing the composition and a solvent, a slit coat method, a capillary coat method, a gravure coat method, a micro gravure coat method, a bar coat method, a knife coat method, a nozzle coat method, an inkjet coat method and a spin coat method are preferable.

From the standpoint of film formability, the surface tension of a solvent at 25° C. is preferably larger than 15 mN/m, more preferably larger than 15 mN/m and smaller than 100 mN/m, further preferably larger than 25 mN/m and smaller than 60 mN/m.

### <Organic Transistor>

The composition of the present invention can be used also in an organic film transistor. The organic film transistor includes those having a source electrode and a drain electrode, an organic semiconductor layer (active layer) acting as a current pathway between these electrodes, and a gate electrode controlling the amount of current passing through this current pathway. Such an organic film transistor includes electric field effect types, electrostatic induction types and the like.

It is preferable that the electric field effect type organic film transistor has a source electrode and a drain electrode, an organic semiconductor layer (active layer) acting as a current pathway between them, a gate electrode controlling the amount of current passing through this current pathway, and an insulation layer disposed between the organic semiconductor layer and the gate electrode. Particularly, it is preferable that the source electrode and the drain electrode are disposed in contact with the organic semiconductor layer (active layer), and further, the gate electrode is disposed sandwiching the insulation layer in contact with the organic semiconductor layer. In the electric field effect type organic film transistor, the organic semiconductor layer is constituted of a film containing the composition of the present invention.

It is preferable that the electrostatic induction type organic film transistor has a source electrode and a drain electrode, an organic semiconductor layer (active layer) acting as a current pathway between them, and a gate electrode controlling the amount of current passing through this current pathway, and this gate electrode is provided in an organic semiconductor layer. Particularly, it is preferable that the source electrode, the drain electrode and the gate electrode provided in the organic semiconductor layer are disposed in contact with the organic semiconductor layer. Here, the structure of the gate electrode may be a structure in which a current pathway flowing from the source electrode to the drain electrode is formed and the amount of current flowing in the current pathway can be controlled by voltage applied to the gate electrode, and for example, a comb-shaped electrode is mentioned. Also in the electrostatic induction type organic film transistor, the organic semiconductor layer is constituted of a film containing the composition of the present invention.

### <Organic Electroluminescent Device>

The composition of the present invention can also be used in an organic electroluminescent device (organic EL device). The organic EL device has a light emitting layer between a pair of electrodes at least one of which is transparent or semi-transparent. The organic EL device may also contain a hole transporting layer and an electron transporting layer, in addition to the light emitting layer. The composition of the present invention is contained in any of the light emitting layer, the hole transporting layer and the electron transporting layer. The light emitting layer may also contain a charge transporting material (meaning a generic name of an electron transporting material and a hole transporting material), in addition to the composition of the present invention. The organic EL device includes a device having an anode, a light emitting layer and a cathode; a device having an anode, a light emitting layer, an electron transporting layer and a cathode, further having an electron transporting layer containing an electron transporting material between the cathode and the light emitting layer in adjacent to the light emitting layer; a device having an anode, a hole transporting layer, a light emitting layer and a cathode, further having a hole transporting layer containing a hole transporting material between the anode and the light emitting layer in adjacent to the light emitting layer; a device having an anode, a hole transporting layer, a light emitting layer, an electron transporting layer and a cathode; and the like.

### <Application of Device>

The organic photoelectric conversion device having the composition of the present invention is irradiated with a light such as sunlight or the like through a transparent or semi-transparent electrode, thereby generating photovoltaic power between electrodes, thus, it can be operated as an organic film solar cell. A plurality of organic film solar batteries can also be integrated and used as an organic film solar cell module.

By irradiating with a light through a transparent or semi-transparent electrode under condition of application of voltage between electrodes or under condition of no application of voltage, photocurrent flows, thus, it can be operated as an organic optical sensor. A plurality of organic optical sensors can also be integrated and used as an organic image sensor.

The above-described organic film transistor can be used, for example, as a picture element driving device used for regulating picture element control, screen luminance uniformity and screen rewriting speed of an electrophoresis display, a liquid crystal display, an organic electroluminescent display and the like.

### <Solar Cell Module>

The organic film solar cell can have a module structure which is basically the same as that of a conventional solar cell module. A solar cell module has generally a structure in which a cell is constituted on a supporting substrate such as a metal, ceramic and the like, the upper side thereof is covered with a filling resin, protective glass and the like and a light is introduced from the opposite side of the supporting substrate, however, it is also possible to provide a structure in which a transparent material such as reinforced glass and the like is used for the supporting substrate, a cell is constituted thereon and a light is introduced from the transparent supporting substrate side. Specifically, module structures called super straight type, sub straight type or potting type, substrate-integrated module structures used in amorphous silicon solar batteries, and the like, are known. For the organic film solar cell produced by using the composition of the present invention, these module structures can be appropriately selected depending on the use object, the use place and environments.

A typical module of super straight type cr sub straight type has a structure in which cells are disposed at regular interval between supporting substrates of which one side or both sides are transparent and on which a reflection preventing treatment has been performed, adjacent cells are mutually connected by a metal lead or flexible wiring and the like, a power collecting electrode is placed on an outer edge part and generated powder is harvested outside. Between the substrate and the cell, various kinds of plastic materials such as ethylene vinyl acetate (EVA) and the like may be used in the form of a film or filling resin depending on the object, for protection of the cell and for improvement in power collecting efficiency. In the case of use at places requiring no covering of the surface with a hard material such as a place receiving little impact from outside, it is possible that the surface protective layer is constituted of a transparent plastic film, or the above-described filling resin is hardened to impart a protective function, and one supporting substrate is omitted. The circumference of the supporting substrate is fixed in the form of sandwich by a metal frame for tight seal of the inside and for securement of rigidity of the module, and a space between the supporting substrate and the frame is sealed tightly with a sealant. If a flexible material is used as the cell itself, or as the supporting substrate, the filling material and the sealant, a solar cell can be constituted also on a curved surface.

In the case of a solar cell using a flexible support such as a polymer film and the like, a cell body can be fabricated by forming cells sequentially while feeding a support in the form of a roll, cutting into a desired size, then, sealing a peripheral part with a flexible moisture-proof material. Also, a module structure called “SCAF” described in Solar Energy Materials and Solar Cells, 48, p 383-391 can be adopted. Further, a solar cell using a flexible support can also be adhered and fixed to curved glass and the like and used.

An organic photoelectric conversion device having an organic layer containing the composition of the present invention can be suitably used in a solar cell module, an image sensor, an organic film transistor and the like because of high photoelectric conversion efficiency.

### EXAMPLES

Examples for illustrating the present invention further in detail will be shown below, but the present invention is not limited to them.

### Synthesis Example 1

### Synthesis of Compound 3

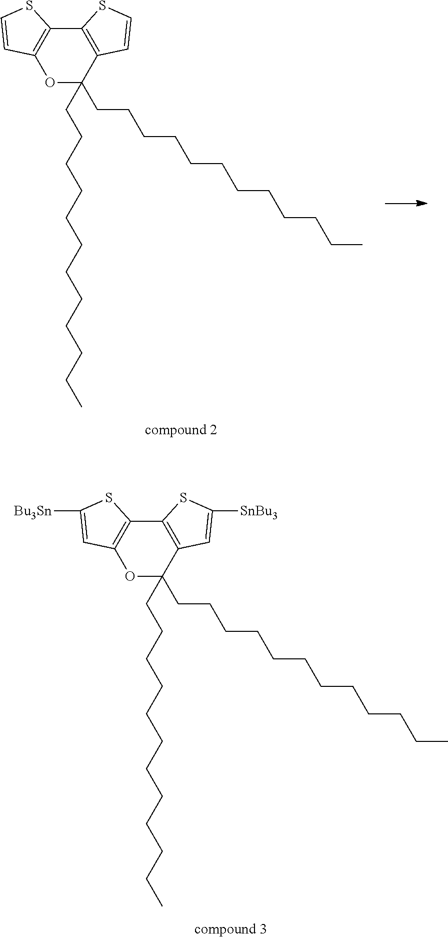

Into a 200 mL flask prepared by purging air in the flask with argon were charged 2.00 g (3.77 mmol) of a compound 2 synthesized according to a method described in WO2011/052709, Example 2 and 100 mL of dehydrated tetrahydrofuran and a uniform solution was obtained. While keeping the solution at −78°, 5.89 mL (9.42 mmol) of a 1.6 M n-butyllithium hexane solution was dropped into the solution over a period of 10 minutes. After dropping, the reaction liquid was stirred at −78° C. for 30 minutes, then, stirred at room temperature (25° C.) for 2 hours. Thereafter, the flask was cooled down to −78° C., and 3.37 g (10.4 mmol) of tributyltin chloride was added to the reaction liquid. After addition, the reaction liquid was stirred at −78° C. for 30 minutes, then, stirred at room temperature (25° C.) for 3 hours. Thereafter, to the reaction liquid was added 200 ml of water to stop the reaction, ethyl acetate was added and the organic layer containing the reaction product was extracted. The organic layer was dried over sodium sulfate, filtrated, then, the filtrate was concentrated by an evaporator, and the solvent was distilled off. The resultant oily substance was purified by a silica gel column using hexane as a developing solvent. As the silica gel in the silica gel column, silica gel prepared by previously immersing in hexane containing 10 wt % of triethylamine for 5 minutes, then, rinsing with hexane was used. After purification, 3.55 g (3.20 mmol) of a compound 3 was obtained.

### Synthesis Example 2

### Synthesis of Polymer Compound A

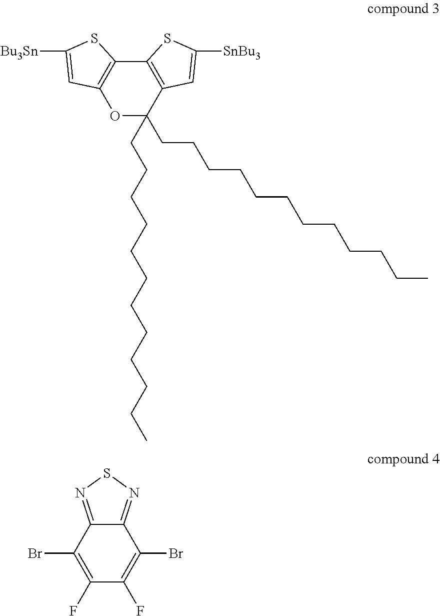

Into a 100 mL flask prepared by purging air in the flask with argon were charged 320 mg (0.289 mmol) of the compound 3, 100 mg (0.303 mmol) of a compound 4 synthesized according to a method described in WO2011/052709, Reference Example 14 and 22 ml of toluene and a uniform solution was obtained. The resultant toluene solution was bubbled with argon for 30 minutes. Thereafter, 4.16 mg (0.0045 mmol) of tris(dibenzylideneacetone)dipalladium and 8.30 mg (0.027 mmol) of tris(2-toluyl)phosphine were added to the toluene solution, and the mixture was stirred at 100° C. for 6 hours. Thereafter, to the reaction liquid was added 88.6 mg of phenyltrimethyltin, and the mixture was further stirred for 5 hours. Thereafter, to the reaction liquid was added 500 mg of phenyl bromide, and the mixture was further stirred for 5 hours. Thereafter, the flask was cooled down to 25° C., and the reaction liquid was poured into 500 mL of methanol. The deposited polymer was collected by filtration, the resultant polymer was placed into a cylindrical paper filter, and extracted with methanol, acetone and hexane, each for 5 hours, using a Soxhlet extractor. The polymer remaining in the cylindrical paper filter was dissolved in 15 mL of o-dichlorobenzene, 0.31 g of sodium diethyldithiocarbamate and 3 mL of water were added, and the mixture was stirred under reflux for 8 hours. After removal of the aqueous layer, the organic layer was washed with 50 ml of water twice, then, washed with 50 mL of a 3 wt % acetic acid aqueous solution twice, then, washed with 50 mL of water twice, and the resultant solution was poured into methanol to cause deposition of a polymer. The polymer was filtrated, then, dried, and the resultant polymer was dissolved again in 20 mL of o-dichlorobenzene, and allowed to pass through an alumina/silica gel column. The resultant solution was poured into methanol to cause deposition of a polymer, which was filtrated, then, dried, to obtain 174 mg of a purified polymer. Hereinafter, this polymer is referred to as a polymer compound A.

### Synthesis Example 3

### Synthesis of Polymer Compound B

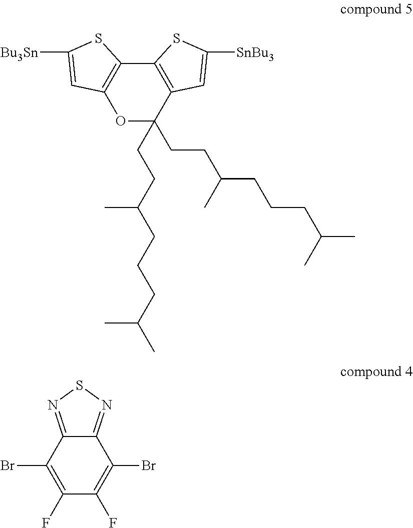

Into a 200 mL flask prepared by purging air in the flask with argon were charged 500 mg (0.475 mmol) of a compound 5 synthesized according to a method described in WO2011/052709, Example 53, 141 mg (0.427 mmol) of a compound 4 synthesized according to a method described in WO2011/052709, Reference Example 14 and 32 ml of toluene and a uniform solution was obtained. The resultant toluene solution was bubbled with argon for 30 minutes. Thereafter, 6.52 mg (0.007 mmol) of tris(dibenzylideneacetone)dipalladium and 13.0 mg of tris(2-toluyl)phosphine were added to the toluene solution, and the mixture was stirred at 100° C. for 6 hours. Thereafter, to the reaction liquid was added 500 mg of phenyl bromide, and the mixture was further stirred for 5 hours. Thereafter, the flask was cooled down to 25° C., and the reaction liquid was poured into 300 mL of methanol. The deposited polymer was collected by filtration, the resultant polymer was placed into a cylindrical paper filter, and extracted with methanol, acetone and hexane, each for 5 hours, using a Soxhlet extractor. The polymer remaining in the cylindrical paper filter was dissolved in 100 mL of toluene, 2 g of sodium diethyldithiocarbamate and 40 mL of water were added, and the mixture was stirred under reflux for 8 hours. After removal of the aqueous layer, the organic layer was washed with 50 ml of water twice, then, washed with 50 mL of a 3 wt % acetic acid aqueous solution twice, washed with 50 mL of water twice, then, washed with 30 mL of a 5 wt % potassium fluoride aqueous solution twice, then, washed with 50 mL of water twice, and the resultant solution was poured into methanol to cause deposition of a polymer. The polymer was filtrated, then, dried, and the resultant polymer was dissolved again in 50 mL of o-dichlorobenzene, and allowed to pass through an alumina/silica gel column. The resultant solution was poured into methanol to cause deposition of a polymer, which was filtrated, then, dried, to obtain 185 mg of a purified polymer. Hereinafter, this polymer is referred to as a polymer compound B.

### Synthesis Example 4

### Synthesis of Compound 6

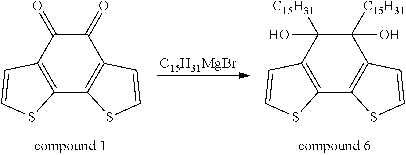

A gas in a 100 mL three-necked flask was changed to a nitrogen gas atmosphere, then, the compound 1 (0.4 g, 1.8 mmol) and dried THF (5.4 mL) were added, and the mixture was heated at 80° C. Thereafter, a n-pentadecylmagnesium bromide-THF solution (10.9 mL, 5.4 mmol) was added at the same temperature, and stirred for 2 hours. Subsequently, water (10 mL) was added to stop the reaction, and the reaction solution was extracted with chloroform twice. The resultant organic layer was washed with a saturated ammonium chloride aqueous solution twice and with saturated saline once, and dried over anhydrous sodium sulfate, and the solvent was distilled off under reduced pressure. The resultant residue was purified by silica gel column chromatography, to obtain a compound 6. The gained amount of the compound 6 was 512 mg, and the yield thereof was 34%.

1H-NMR (300 MHz, CO(CD3)2): δ (ppm)=7.25 (d, 2H), 7.20 (d, 2H), 3.83 (s, 2H), 2.0-1.0 (m, 56H), 0.93 (t, 6H).

### Synthesis Example 5

### Synthesis of Compound 7

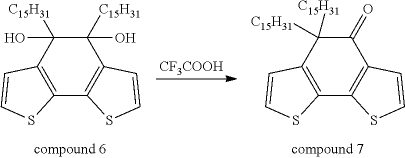

An atmosphere in a 100 mL three-necked flask was changed to a nitrogen gas atmosphere, then, the compound 6 (0.5 g, 0.77 mmol), acetic acid (40 mL) and trifluoroacetic acid (20 mL) were added, and the mixture was heated at 80° C. for 1 hour. After completion of the reaction, the reaction solution was poured into 300 mL of water, and the mixture was extracted with toluene twice. The resultant organic layer was washed with a saturated sodium hydrogen carbonate aqueous solution three times, dried over anhydrous magnesium sulfate, and the solvent was distilled off under reduced pressure. The resultant residue was purified by silica gel column chromatography, to obtain a compound 7. The gained amount of the compound 7 was 451 mg, and the yield thereof was 93%. The compound 7 was further synthesized in an analogous manner.

1H-NMR (CDCl3): δ (ppm)=7.44 (d, 1H), 7.34 (d, 1H), 7.05 (d, 1H), 6.98 (d, 1H), 2.16 (m, 2H), 1.72 (m, 2H), 1.24 (m, 52H), 0.87 (t, 6H).

### Synthesis Example 6

### Synthesis of Compound 8

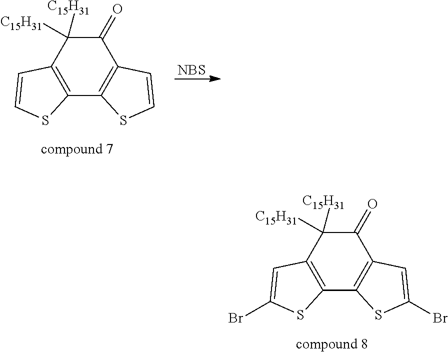

A gas in a 100 mL three-necked flask was changed to a nitrogen gas atmosphere, then, the compound 7 (0.887 g, 1.4 mmol), dried DMF (140 mL) and N-bromosuccinic acid imide (554 mg, 3.11 mmol) were added, and the mixture was heated at 60° C. for 4 hours. After completion of the reaction, the reaction solution was cooled down to room temperature, then, was (200 ml) was added, and the mixture was extracted with toluene (50 mL) twice. The resultant organic layer was washed with a saturated sodium thiosulfate aqueous solution (50 mL) and saturated saline (50 mL), then, dried over anhydrous magnesium sulfate, and the solvent was distilled off under reduced pressure. Purification was performed in a middle pressure preparative column, to obtain a compound 8. The gained amount of the compound 8 was 1.02 g, and the yield thereof was 938.

1H-NMR (CDCl3): δ (ppm)=7.40 (s, 1H), 6.95 (s, 1H), 2.16 (m, 2H), 1.72 (m, 2H), 1.24 (m, 52H), 0.87 (t, 6H).

### Synthesis Example 7

### Synthesis of Polymer Compound C)

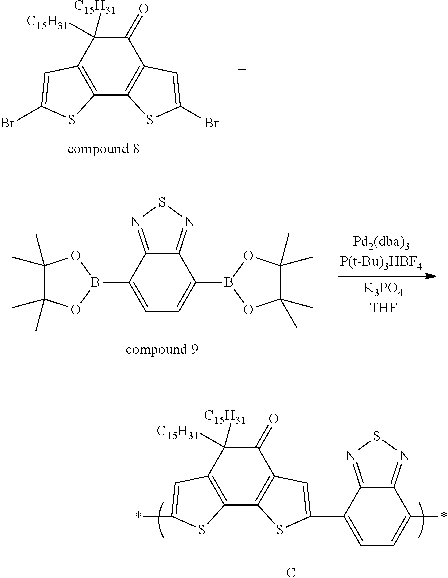

A gas in a 100 mL four-necked flask was changed to a nitrogen gas atmosphere, then, the compound 8 (471 mg, 0.60 mmol) and dried THF (11 mL) were added, and the mixture was deaerated by bubbling with an argon gas for 30 minutes. Thereafter, tris(dibenzylideneacetone)dipalladium (27.5 mg, 0.03 mmol), tri-tert-butylphosphonium tetrafluoroborate (34.8 mg, 0.12 mmol) and a 3M potassium phosphate aqueous solution (1.4 mL) were added, and the mixture was heated at 80° C. A dried chlorobenzene (11.4 mL) solution of the compound 9 (211.9 mg, 0.546 mmol) deaerated by bubbling with an argon gas for 30 minutes was dropped at 80° C. into this reaction solution over a period of 5 minutes, and the mixture was stirred at 80° C. for 3 hours. A dried THF (7 mL) solution of phenylboronic acid (73.2 mg) deaerated by bubbling with an argon gas for 30 minutes was added to this reaction solution, and the mixture was stirred at 80° C. for 2 hours, then, sodium N,N-diethyldithio carbamate tri-hydrate (1.7 g) and water (15 g) were added, and the mixture was further stirred at 80° C. for 2 hours. The aqueous layer in the resultant reaction solution was removed, then, the organic layer was washed with water (20 g) once, a 10 wt % acetic acid aqueous solution (20 g) twice and water (20 g) once, then, acetone (400 mL) was used to cause re-precipitation. The resultant solid was purified by silica gel column chromatography, and re-precipitated by using methanol, to obtain 261 mg of a polymer compound C. The ionization potential of the organic film containing the polymer compound C was 5.6 eV.

### Synthesis Example 8

### Synthesis of Compound 10

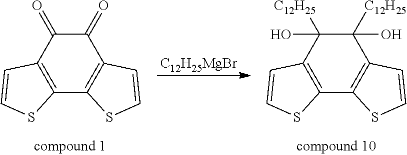

A gas in a 100 mL three-necked flask was changed to a nitrogen gas atmosphere, then, the compound 1 (5 g, 22.7 mmol) and dried THF (300 mL) were added, and the mixture was heated at 80° C. Thereafter, a diethyl ether solution of n-dodecylmagnesium bromide (90.8 mL, 90.8 mmol) was added at the same temperature and the mixture was stirred for 2.5 hours. Subsequently, water (30 mL) was added to stop the reaction, further, 10 mL of acetic acid was added, and the reaction solution was extracted with chloroform twice. The resultant organic layer was washed with a saturated ammonium chloride aqueous solution twice, saturated saline once, and dried over anhydrous sodium sulfate, and the solvent was distilled off under reduced pressure. The resultant residue was purified by silica gel column chromatography, to obtain a compound 10. The yielded amount of the compound 10 was 8.5 g, and the yield thereof was 67%.

### Synthesis Example 9

### Synthesis of Compound 11

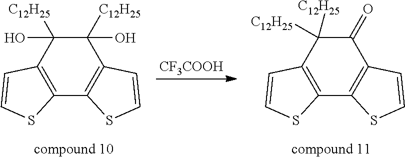

A gas in a 100 mL three-necked flask was changed to a nitrogen gas atmosphere, then, the compound 10 (8.5 g, 15.2 mmol), acetic acid (200 mL) and trifluoroacetic acid (50 mL) were added, and the mixture was heated at 80° C. for 1 hour. After completion of the reaction, the reaction solution was poured into 200 mL of water, and the mixture was extracted with toluene twice. The resultant organic layer was washed with a saturated sodium hydrogen carbonate aqueous solution three times, and dried over anhydrous magnesium sulfate, and the solvent was distilled off under reduced pressure. The resultant residue was purified by silica gel column chromatography, to obtain a compound 11. The gained amount of the compound 11 was 6.28 g (11.6 mmol), and the yield thereof was 76%.

1H-NMR (CDCl3): δ (ppm)=7.44 (d, 1H), 7.34 (d, 1H), 7.05 (d, 1H), 6.98 (d, 1H), 2.16 (m, 2H), 1.72 (m, 2H), 1.24 (m, 40H), 0.87 (t, 6H).

### Synthesis Example 10

### Synthesis of Compound 12

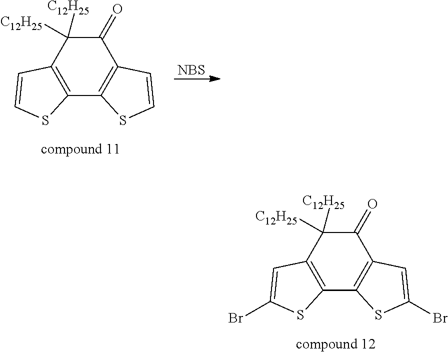

A gas in a 500 mL three-necked flask was changed to a nitrogen gas atmosphere, then, the compound 11 (6.28 g, 11.6 mmol), chloroform (100 mL), acetic acid (100 mL) and N-bromosuccinic acid imide (4.53 g, 25.4 mmol) were added, and the mixture was heated at 65° C. for 1 hour. After completion of the reaction, the reaction solution was cooled down to room temperature, then, water (300 ml) was added, and the mixture was extracted with chloroform (100 mL) twice. The resultant organic layer was washed with a saturated sodium thiosulfate aqueous solution (50 mL), saturated saline (50 mL), then, dried over anhydrous magnesium sulfate, and the solvent was distilled off under reduced pressure. The product was purified by silica gel column chromatography using a hexane/chloroform mixed solvent (hexane:chloroform=8:1 (vol/vol)) as an elution solvent, to obtain a compound 12. The gained amount of the compound 12 was 6.74 g, and the yield thereof 83%.

1H-NMR (CDCl3): δ (ppm)=7.40 (s, 1H), 6.95 (s, 1H), 2.16 (m, 2H), 1.72 (m, 2H), 1.24 (m, 40H), 0.87 (t, 6H).

### Synthesis Example 11

### Synthesis of Polymer Compound D)

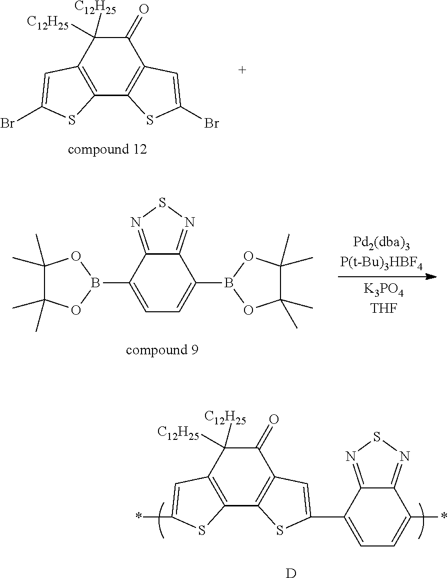

A gas in a 100 mL four-necked flask was changed to a nitrogen gas atmosphere, then, the compound 12 (200 mg, 0.515 mmol) and dried THF (14 mL) were added, and the mixture as deaerated by bubbling with an argon gas for 30 minutes. Thereafter, tris(dibenzylideneacetone)dipalladium (23.6 mg, 0.0258 mmol), tri-tert-butylphosphonium tetrafluoroborate (29.9 mg, 0.103 mmol) and a 3M potassium phosphate aqueous solution (2 mL) were added, and the mixture was heated at 80° C. A dried chlorobenzene (14 mL) solution of the compound 9 (361 mg, 0.515 mmol) deaerated by bubbling with an argon gas for 30 minutes was dropped at 80° C. into this reaction solution over a period of 5 minutes, and the mixture was stirred at 80° C. for 3 hours. A dried THF (5 mL) solution of phenyl boronic acid (40 mg) deaerated by bubbling with an argon gas for 30 minutes was added to this reaction solution, and the mixture was stirred at 80° C. for 2 hours, then, sodium N,N-diethyldithiocarbamate tri-hydrate (1.7 g) and water (15 g) were added, and the mixture was further stirred at 80° C. for 2 hours. The aqueous layer in the resultant reaction solution was removed, then, the organic layer was washed with water (20 g) once, a 10 wt % acetic acid aqueous solution (20 g) twice and water (20 g) once, then, acetone (300 mL) was used to cause re-precipitation. The resultant solid was purified by silica gel column chromatography, and re-precipitated by using methanol, to obtain 283 mg of a polymer compound D. The ionization potential of the organic film containing the polymer compound D was 5.6 eV.

### Example 1

### Fabrication and Evaluation of Organic Film Solar Cell

A glass substrate carrying thereon an ITO film having a thickness of 150 nm formed by sputtering method was irradiated with ultraviolet ray using a UV ozone washing apparatus, thereby performing a surface treatment. Next, the polymer compound A, the polymer compound B and fullerene C60PCBM (phenyl-C61-butyric acid methyl ester, manufactured by Frontier Carbon Corporation) were dissolved in orthodichlorobenzene so that the ratio of the weight of the polymer compound B to the weight of the polymer compound A was 1 and the ratio of the weight of C60PCBM to the weight of a mixture of the polymer compound A and the polymer compound B was 2, to produce an ink 1. In the ink 1, the sum of the weight of the polymer compound A, the weight of the polymer compound B and the weight of C60PCBM was 1.5% by weight with respect to the weight of the ink 1. The ink 1 was coated on the ITO film on the glass substrate by spin coating, to fabricate an organic film containing the polymer compound A, the polymer compound B and C60PCBM. The thickness of the organic film was about 100 nm. The light absorption end wavelength of the organic film was measured, to find a value of 880 nm. Thereafter, a solution containing titanium(IV) isopropoxide (manufactured by Sigma-Aldrich) was coated on the organic film by spin coating, to form a titanium oxide film. Then, Al was vapor-deposited with a thickness of about 100 nm on the titanium oxide film, to fabricate an organic film solar cell. The shape of the resultant organic film solar cell was 2 mm×2 mm square. The resultant organic film solar cell was irradiated with a constant light using Solar Simulator (manufactured by Bunkoukeiki, Co., Ltd., trade name: CEP-2000: AM 1.5G filter, irradiance: 100 mW/cm²), the generated current and voltage were measured, and the photoelectric conversion efficiency, the short circuit current density, the open circuit voltage and the fill factor were determined. Jsc (short circuit current density) was 13.6 mA/cm², Voc (open circuit voltage) was 0.71 V, FF (fill factor) was 0.65 and the photoelectric conversion efficiency (ii) was 6.3.

### Comparative Example 1

### Fabrication and Evaluation of Organic Film Solar Cell

A glass substrate carrying thereon an ITO film having a thickness of 150 nm formed by sputtering method was irradiated with ultraviolet ray using a UV ozone washing apparatus, thereby performing a surface treatment. Next, the polymer compound A and fullerene C60PCBM (phenyl-C61-butyric acid methyl ester, manufactured by Frontier Carbon Corporation) were dissolved in orthodichlorobenzene so that the ratio of the weight of C60PCBM to the weight of the polymer compound A was 2, to produce an ink 2. In the ink 2, the sum of the weight of the polymer compound A and the weight of C60PCBM was 1.5% by weight with respect to the weight of the ink 2. The ink 2 was coated on the ITO film on the glass substrate by spin coating, to fabricate an organic film containing the polymer compound A and C60PCBM. The thickness of the organic film was about 100 nm. The light absorption end wavelength of the organic film was measured, to find a value of 880 nm. Thereafter, a solution containing titanium(IV) isopropoxide (manufactured by Sigma-Aldrich) was coated on the organic film by spin coating, to form a titanium oxide film. Then, Al was vapor-deposited with a thickness of about 100 nm on the titanium oxide film, to fabricate an organic film solar cell. The shape of the resultant organic film solar cell was 2 mm×2 mm square. The resultant organic film solar cell was irradiated with a constant light using Solar Simulator (manufactured by Bunkoukeiki, Co., Ltd., trade name: CEP-2000: AM 1.5G filter, irradiance: 100 mW/cm²), the generated current and voltage were measured, and the photoelectric conversion efficiency, the short circuit current density, the open circuit voltage and the fill factor were determined. Jsc (short circuit current density) was 10.5 mA/cm², Voc (open circuit voltage) was 0.69 V, FF (fill factor) was 0.65 and the photoelectric conversion efficiency (η) was 4.7%.

### Comparative Example 2

### Fabrication and Evaluation of Organic Film Solar Cell

An organic film solar cell was fabricated in the same manner as in Comparative Example 1 excepting that the polymer compound B was used instead of the polymer compound A, and the photoelectric conversion efficiency, the short circuit current density, the open circuit voltage and the fill factor were determined. The light absorption end wavelength of the organic film containing the polymer compound B and fullerene C60PCBM was 890 nm. Jsc (short circuit current density) was 13.8 mA/cm², Voc (open circuit voltage) was 0.72 V, FF (fill factor) was 0.58 and the photoelectric conversion efficiency (η) was 5.8%.

### Example 2

### Fabrication and Evaluation of Organic Film Solar Cell

A glass substrate carrying thereon an ITO film having a thickness of 150 nm formed by sputtering method was irradiated with ultraviolet ray using a UV ozone washing apparatus, thereby performing a surface treatment. Next, the polymer compound C, the polymer compound D and fullerene C60PCBM (phenyl-C61-butyric acid methyl ester, manufactured by Frontier Carbon Corporation) were dissolved in orthodichlorobenzene so that the ratio of the weight of the polymer compound D to the weight of the polymer compound C was 1 and the ratio of the weight of C60PCBM to the weight of a mixture of the polymer compound C and the polymer compound D was 2.5, to produce an ink 3. In the ink 3, the sum of the weight of the polymer compound C, the weight of the polymer compound D and the weight of C60PCBM was 1.75% by weight with respect to the weight of the ink 3. The ink 3 was coated on the ITO film on the glass substrate by spin coating, to fabricate an organic film containing the polymer compound C, the polymer compound D and C60PCBM. The thickness of the organic film was about 100 nm. The light absorption end wavelength of the organic film was measured, to find a value of 740 nm. Thereafter, a solution containing titanium(IV) isopropoxide (manufactured by Sigma-Aldrich) was coated on the organic film by spin coating, to form a titanium oxide film. Then, Al was vapor-deposited with a thickness of about 100 nm on the titanium oxide film, to fabricate an organic film solar cell. The shape of the resultant organic film solar cell was 2 mm×2 mm square. The resultant organic film solar cell was irradiated with a constant light using Solar Simulator (manufactured by Bunkoukeiki, Co., Ltd., trade name: CEP-2000: AM 1.5G filter, irradiance: 100 mW/cm²), the generated current and voltage were measured, and the photoelectric conversion efficiency, the short circuit current density, the open circuit voltage and the fill factor were determined. Jsc (short circuit current density) was 9.9 mA/cm², Voc (open circuit voltage) was 1.08 V, FF (fill factor) was 0.63 and the photoelectric conversion efficiency (in) was 6.7%.

### Comparative Example 3

### Fabrication and Evaluation of Organic Film Solar Cell

A glass substrate carrying thereon an ITO film having a thickness of 150 nm formed by sputtering method was irradiated with ultraviolet ray using a UV ozone washing apparatus, thereby performing a surface treatment. Next, the polymer compound C and fullerene C60PCBM (phenyl-C61-butyric acid methyl ester, manufactured by Frontier Carbon Corporation) were dissolved in orthodichlorobenzene so that the ratio of the weight of C60PCBM to the weight of the polymer compound C was 2.5, to produce an ink 4. In the ink 4, the sum of the weight of the polymer compound C and the weight of C60PCBM was 1.75% by weight with respect to the weight of the ink 4. The ink 4 was coated on the ITO film on the glass substrate by spin coating, to fabricate an organic film containing the polymer compound C and C60PCBM. The thickness of the organic film was about 100 nm. The light absorption end wavelength of the organic film was measured, to find a value of 740 nm. Thereafter, a solution containing titanium(IV) isopropoxide (manufactured by Sigma-Aldrich) was coated on the organic film by spin coating, to form a titanium oxide film. Then, Al was vapor-deposited with a thickness of about 100 nm on the titanium oxide film, to fabricate an organic film solar cell. The shape of the resultant organic film solar cell was 2 mm×2 mm square. The resultant organic film solar cell was irradiated with a constant light using Solar Simulator (manufactured by Bunkoukeiki, Co., Ltd., trade name: CEP-2000: AM 1.5G filter, irradiance: 100 mW/cm²), the generated current and voltage were measured, and the photoelectric conversion efficiency, the short circuit current density, the open circuit voltage and the fill factor were determined. Jsc (short circuit current density) was 9.9 mA/cm², Voc (open circuit voltage) was 1.09 V, FF (fill factor) was 0.60 and the photoelectric conversion efficiency (n) was 6.5%.

### Comparative Example 4

### Fabrication and Evaluation of Organic Film Solar Cell

An organic film solar cell was fabricated in the same manner as in Comparative Example 3 excepting that the polymer compound D was used instead of the polymer compound C, and the photoelectric conversion efficiency, the short circuit current density, the open circuit voltage and the fill factor were determined. The light absorption end wavelength of the organic film containing the polymer compound D and fullerene C60PCBM was 740 nm. Jsc (short circuit current density) was 9.8 mA/cm², Voc (open circuit voltage) was 1.06 V, FF (fill factor) was 0.56 and the photoelectric conversion efficiency (η) was 5.8%.

TABLE 1
results of evaluation of organic film solar cell

| | short | | | |
|---|---|---|---|---|
| | circuit | open | | photoelectric |
| | current | circuit | | conversion |
| | density | voltage | fill | efficiency |
| | (mA/cm²) | (V) | factor | (%) |
| Example 1 | 13.6 | 0.71 | 0.65 | 6.3 |
| Comparative | 10.5 | 0.69 | 0.65 | 4.7 |
| Example 1 | | | | |
| Comparative | 13.8 | 0.72 | 0.58 | 5.8 |
| Example 2 | | | | |
| Example 2 | 9.9 | 1.08 | 0.63 | 6.7 |
| Comparative | 9.9 | 1.09 | 0.60 | 6.5 |
| Example 3 | | | | |
| Comparative | 9.8 | 1.06 | 0.56 | 5.8 |
| Example 4 | | | | |

1. A composition comprising a first compound, a second compound and a third compound, wherein the first compound is a polymer compound having a constitutional unit represented by the formula (1), the second compound is a polymer compound having a constitutional unit represented by the formula (2) and the third compound is a compound different from the first compound and the second compound: 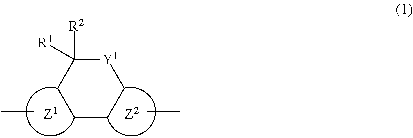
(wherein R¹ and R² represent each independently a hydrogen atom or a substituent; Y¹ represents an oxygen atom, a sulfur atom, —C(═O)— or —N(R⁵)—; R⁵ represents a hydrogen atom or a substituent; ring Z¹ and ring Z² represent each independently an aromatic carbocyclic ring which may have a substituent or a heterocyclic ring which may have a substituent; 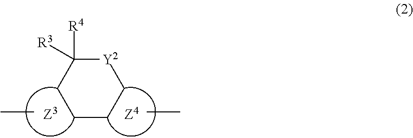
(wherein R³ and R⁴ represent each independently a hydrogen atom or a substituent, provided that R³ and R⁴ are different from R¹ and R²; Y² represents an oxygen atom, a sulfur atom, —C(═O)— or —N(R⁵)—; R⁵ represents a hydrogen atom or a substituent; ring Z³ and ring Z⁴ represent each independently an aromatic carbocyclic ring which may have a substituent or a heterocyclic ring which may have a substituent.

2. The composition according to claim 1, wherein Y′ and Y² represent each independently an oxygen atom, a sulfur atom or —N(R⁵)—.

3. The composition according to claim 1, wherein R¹ and R² are both a branched alkyl group, or R¹ and R² are both a linear alkyl group.

4. The composition according to claim 1, wherein R¹ and R² are both a branched alkyl group.

5. The composition according to claim 1, wherein R³ and R⁴ are both a branched alkyl group, or R³ and R⁴ are both a linear alkyl group.

6. The composition according to claim 1, wherein R³ and R⁴ are both a linear alkyl group.

7. The composition according to claim 1, wherein R¹, R², R³ and R⁴ have each independently a number of carbon atoms of 10 to 15.

8. The composition according to claim 1, wherein at least one of the polymer compound having a constitutional unit represented by the formula (1) and the polymer compound having a constitutional unit represented by the formula (2) is a polymer compound further containing a constitutional unit represented by the formula (3): 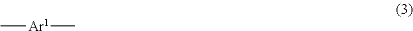
(wherein Ar¹ is different from the constitutional unit represented by the formula (1) and the constitutional unit represented by the formula (2) and represents an arylene group which may have a substituent or a divalent heterocyclic group which may have a substituent.

9. The composition according to claim 8, wherein Ar¹ is a constitutional unit represented by the formula (3-1), a constitutional unit represented by the formula (3-2), a constitutional unit represented by the formula (3-3), a constitutional unit represented by the formula (3-4), a constitutional unit represented by the formula (3-5), a constitutional unit represented by the formula (3-6), a constitutional unit represented by the formula (3-7) or a constitutional unit represented by the formula (3-8): 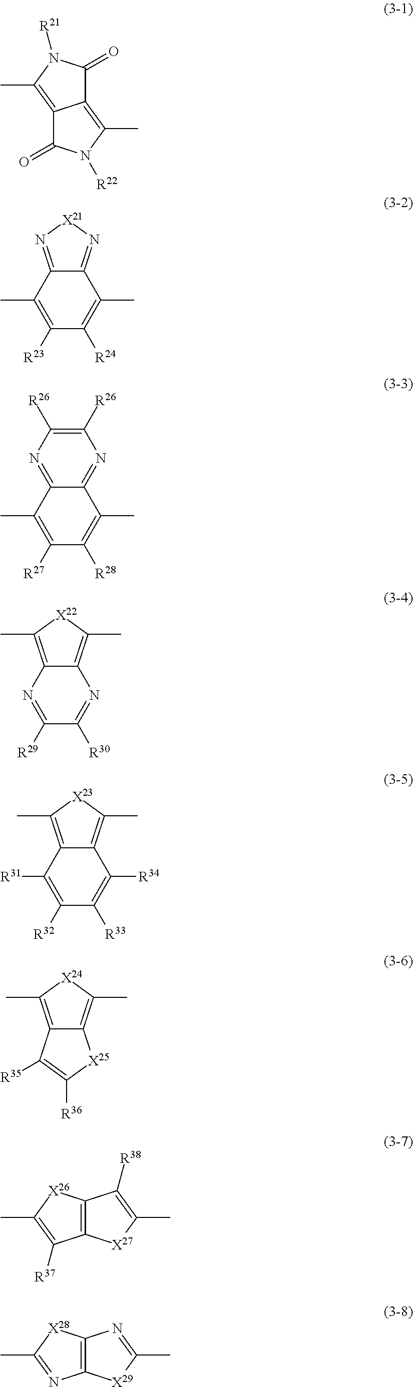
(in the formulae (3-1) to (3-8), R²¹, R²², R²³, R²⁴, R²⁵, R²⁶, R²⁷, R²⁸, R²⁹, R³⁰, R³¹, R³², R³³, R³⁴, R³⁵, R³⁶, R³⁷ and R³⁸ represent each independently a hydrogen atom or a substituent; X²¹, X²², X²³, X²⁴, X²⁵, X²⁶, X²⁷, X²⁸ and X²⁹ represent each independently a sulfur atom, an oxygen atom or a selenium atom.

10. The composition according to claim 1, wherein third compound is an electron accepting compound.

11. The composition according to claim 10, wherein the electron accepting compound is a fullerene or fullerene derivative.

12. A film comprising the composition according to claim 1.

13. A liquid comprising the composition according to claim 1 and a solvent.

14. An electronic device comprising the composition according to claim 1.

15. An organic photoelectric conversion device having a first electrode and a second electrode, having an active layer between the first electrode and the second electrode, and comprising the composition according to claim 1 in the active layer.

16. A solar cell module comprising the organic photoelectric conversion device according to claim 15.

17. An image sensor comprising the organic photoelectric conversion device according to claim 15.

18. An organic film transistor having a gate electrode, a source electrode, a drain electrode and an active layer, and comprising the composition according to claim 1 in the active layer.
